(19) United States
(12) Patent Application Publication
(10) Pub. No.: US 2009/0001885 A1
(43) Pub. Date: Jan. 1, 2009

(54) TANDEM OLED DEVICE

(76) Inventors: Jeffrey P. Spindler, Rochester, NY (US); Tukaram K. Hatwar, Penfield, NY (US); Tommie L. Royster, JR., Rochester, NY (US)

Correspondence Address: EASTMAN KODAK COMPANY;PATENT LEGAL STAFF, 343 STATE STREET, ROCHESTER, NY, 14650-2201, US

(21) Appl. No.: 11/769,349

(22) Filed: Jun. 27, 2007

(51) Int. Cl. H01L 51/52

(52) U.S. Cl. 313/506

(57) ABSTRACT

A tandem OLED device having two spaced electrodes comprising first and second light-emitting units disposed between the electrodes wherein each light emitting unit has at least one light emitting layer with an intermediate connector disposed between each of the light-emitting units. The intermediate connector includes an electron accepting organic layer in contact with the first light emitting unit and an n-type doped organic layer in contact with the electron accepting organic layer and the second light-emitting unit. The n-type doped organic layer includes an organic gallium complex. The devices exhibit improved stability and little change in color when current density is varied.

### CROSS REFERENCE TO RELATED APPLICATIONS

Reference is made to commonly assigned U.S. patent application Ser. No. 11/746,290, filed May 9, 2007, by Jeffrey Spindler et al., entitled “High-Performance Tandem White OLED”, the disclosure of which is incorporated herein by reference.

### FIELD OF THE INVENTION

The present invention relates to providing a plurality of organic electroluminescent (EL) units to form a tandem organic electroluminescent device having improved EL performance.

### BACKGROUND OF THE INVENTION

Organic electroluminescent (EL) devices or organic light-emitting diodes (OLEDs) are electronic devices that emit light in response to an applied potential. The structure of an OLED includes, in sequence, an anode, an organic EL unit, and a cathode. The organic EL unit disposed between the anode and the cathode is commonly comprised of an organic hole-transporting layer (HTL) and an organic electron-transporting layer (ETL). Holes and electrons recombine and emit light in the ETL near the interface of HTL/ETL. Tang et al., “Organic Electroluminescent Diodes”, Applied Physics Letters, 51, 913 (1987), and commonly assigned U.S. Pat. No. 4,769,292 demonstrated highly efficient OLEDs using such a layer structure. Since then, numerous OLEDs with alternative layer structures have been disclosed. For example, there are three layer OLEDs that contain an organic light-emitting layer (LEL) between the HTL and the ETL, such as that disclosed by Adachi et al., “Electroluminescence in Organic Films with Three-Layer Structure”, Japanese Journal of Applied Physics, 27, L269 (1988), and by Tang et al., “Electroluminescence of Doped Organic Thin Films”, Journal of Applied Physics, 65, 3610 (1989). The LEL commonly includes a host material doped with a guest material wherein the layer structures are denoted as HTL/LEL/ETL. Further, there are other multilayer OLEDs that contain more functional layers in the devices. At the same time, many kinds of EL materials are also synthesized and used in OLEDs. These new structures and new materials have further resulted in improved device performance.

An OLED is actually a current driven device. Its luminance is proportional to current density, but its lifetime is inversely proportional to current density. In order to achieve high brightness, an OLED has to be operated at a relatively high current density, but this will result in a short lifetime. Thus, it is critical to improve the luminous efficiency of an OLED while operating at the lowest possible current density consistent with the intended luminance requirement to increase the operational lifetime.

In order to dramatically improve luminous efficiency and to increase lifetime in OLED, a tandem OLED (or stacked OLED, or cascaded OLED) structure, which is fabricated by stacking several individual OLEDs vertically and driven by only a single power source, has been fabricated (see U.S. Pat. Nos. 6,337,492, 6,107,734, 6,717,358, U.S. Patent Publication Nos. 2003/0170491 A1, 2003/0189401 A1, and JP Patent Publication No. 2003045676A). In a tandem OLED having a number of N (N>1) EL units, the luminous efficiency can be N times as high as that of a conventional OLED containing only one EL unit (of course, the drive voltage can also be N times as high as that of the conventional OLED). Therefore, in one aspect to achieve long lifetime, the tandem OLED needs only about 1/N of the current density used in the conventional OLED to obtain the same luminance while the lifetime of the tandem OLED will be about N times that of the conventional OLED. In the other aspect to achieve high luminance, the tandem OLED needs only the same current density used in the conventional OLED to obtain a luminance N times as high as that of the conventional OLED while maintaining about the same lifetime.

Although tandem OLEDs have many advantages, one disadvantage is the increased drive voltage. In many electronic systems, e.g., in some active matrix designs, the available voltage is limited. Thus, there is a need to reduce the voltage necessary to drive tandem OLEDs. One way to lower driving voltage in a tandem OLED is to provide a connecting layer between EL units, wherein the connector layer includes an n-type doped organic layer, which typically includes an electron-transporting material doped with a low-work function metal. However, the doped metal can cause excited-state quenching and lower the luminance efficiency. This occurs if the n-type doped organic layer is directly on the light-emitting layer, or if the electron-transporting material selected for the n-type doped organic layer does not effectively bind the metal dopant, thus permitting diffusion of the metal into the light-emitting layer. Such a situation also shortens the lifetime of the OLED device.

In addition to continued need to provide OLEDs having improved lifetime and efficiency, it is desirable to improve manufacturability of OLED devices. One way to simplify manufacturing is to reduce shadow mask patterning and instead provide a white light-emitting OLED with color filters. For lowest power consumption, it is often advantageous for the chromaticity of the white light-emitting OLED to be close to CIE D₆₅, i.e., CIE x=0.31 and CIE y=0.33. This is particularly the case for so-called RGBW displays having red, green, blue, and white pixels. When using tandem architecture to make a white light-emitting OLED, therefore, it can be important that the chromaticity remain near CIE D₆₅. That is, structural modifications of the tandem structure to reduce voltage should still permit a chromaticity near CIE D₆₅. Similarly, for predictable manufacturing, it is useful if the color of a single EL unit white-emitting OLED is nearly the same in a tandem configuration.

Various improvements in connecting layers for tandem OLED devices have been described in U.S. Pat. No. 7,126,267, U.S. Pat. No. 6,991,859, U.S. Pat. No. 6,717,358, U.S. Pat. No. 7,075,231, U.S. Pat. No. 6,936,961, U.S. Pat. No. 6,872,472, US App 20070046189, US App 2006188745, US App 20060240277, US App 20040185297, US App 20070001587 and US 20040227460.

Gallium complexes in OLED devices have been described in U.S. Pat. No. 6,001,284 and US App 20050191519. In particular, US App 20070003786 describes the use of gallium (III) complexes with bidentate nitrogen ligands.

### SUMMARY OF THE INVENTION

It is an object of the present invention to make an improved tandem OLED device having a long lifetime and little change in color when current density is varied.

It is a further object of the present invention to make a tandem broadband or white light-emitting OLED device having long lifetime with low drive voltage, high efficiency with appropriate and invariant chromaticity.

In one embodiment, these objects are achieved by a tandem OLED device having two spaced electrodes comprising:

a) first and second light-emitting units disposed between the electrodes wherein each light emitting unit has at least one light emitting layer

b) an intermediate connector disposed between each of the light-emitting units and having:
i) an electron accepting organic layer in contact with the first light emitting unit and an n-type doped organic layer in contact with the electron accepting organic layer and the second light emitting unit and wherein the n-type doped organic layer includes an organic gallium complex.

In a second embodiment, these objects are achieved by a tandem OLED device having two spaced electrodes comprising:

a) first and second light-emitting units disposed between the electrodes that produce different emission spectra, the first light-emitting unit produces light that has multiple peaks at wavelengths longer than 500 nm and substantially no emission at wavelengths shorter than 480 nm, and the second light-emitting unit produces light that has substantial emission at wavelengths shorter than 500 nm; and

b) an intermediate connector disposed between each of the light-emitting units and having an electron accepting organic layer and an n-type doped organic layer and wherein the n-type doped organic layer includes an organic gallium complex.

### BRIEF DESCRIPTION OF THE DRAWINGS

FIG. 1 depicts a schematic cross sectional view of a tandem OLED, having N (N≧1) EL units connected in series by N−1 intermediate connectors.

FIG. 2 depicts a schematic cross sectional view of a specific tandem OLED, having two EL units connected in series by an intermediate connector.

FIG. 3 depicts a schematic cross sectional views of a tandem OLED, having two EL units connected in series by an intermediate connector in which the n-type doped organic layer is split into two sublayers.

FIG. 4 shows the dependence of CIEₓ and CIE_{y} chromaticities relative to the current density for the inventive example 1-2 (solid lines) and the comparative example 1-1 (dashed lines).

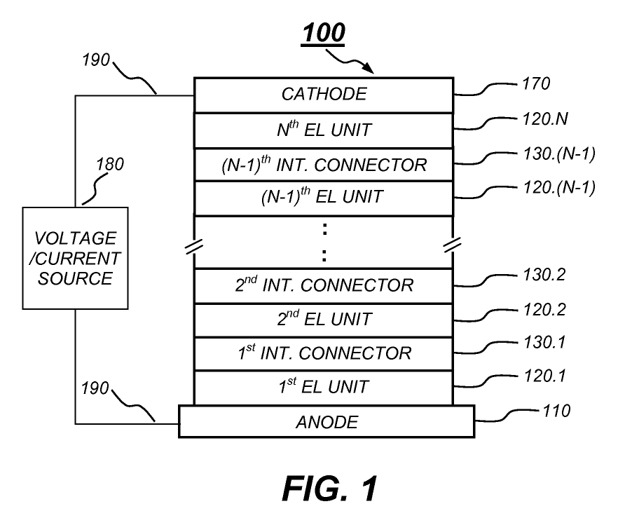

It will be understood that FIGS. 1-3 are not to scale since the individual layers are too thin and the thickness differences of various layers too great to permit depiction to scale.

### DETAILED DESCRIPTION OF THE INVENTION

Several terms to be used in the following description are explained herein. The term “full color” is employed to describe the emission color in the red, green, and blue regions of the visible spectrum. The red, green, and blue colors constitute the three primary colors from which other colors can be produced by appropriate mixing. Broadband emission is light that has significant components in multiple portions of the visible spectrum, for example, blue and green. Broadband emission can also include the situation where light is emitted in the red, green, and blue portions of the spectrum in order to produce white light. White light is that light that is perceived by a user as having a white color, or light that has an emission spectrum sufficient to be used in combination with color filters to produce a practical full color displays. Although the white light can have a strong hue and still be useful, preferably, white color has Commission Internationale de l' Eclairage (CIE) coordinates of about CIEₓ=0.31±0.05 and CIE_{y}=0.33±0.05. This is the color of a D₆₅ white, which is particularly advantages for RGBW displays having red, green, blue, and white pixels as described in WO 2004/061963. The term “pixel” is employed in its art-recognized usage to designate an area of a display panel that can be stimulated to emit light independently. A “high work function metal” is defined as a metal having a work function no less than 4.0 eV. Likewise, a “low work function metal” is defined as a metal having a work function less than 4.0 eV.

In order to appreciate the construction and the performance of the tandem OLED device comprising a plurality of EL units in the present invention, FIGS. 1-3 show the schematics of some embodiments.

FIG. 1 shows a tandem OLED 100 in accordance with the present invention. This tandem OLED has an anode 110 and a cathode 170, at least one of which is transparent. Disposed between the anode and the cathode are N EL units and N−1 intermediate connector (each of them indicated as “int. connector” in the figure), where N is an integer greater than 1. The EL units, stacked and connected serially, are designated 120.1 to 120.N, where 120.1 is the first EL unit (adjacent to the anode), 120.2 is the second EL unit, 120.N−1 is the (N−1)^{th} EL unit, and 120.N is the N^{th} EL unit (nearby the cathode). The intermediate connectors, disposed between the EL unit, are designated 130.1 to 130.(N−1), where 130.1 is the first intermediate connector disposed between EL units 120.1 and 120.2; 130.2 is the second intermediate connector in contact with EL unit 120.2 and another EL unit (not shown in the figure); and 130.(N−1) is the last intermediate connector disposed between EL units 120.(N−1) and 120.N. The tandem OLED 100 is externally connected to a voltage/current source 180 through electrical conductors 190.

The anode 110 and cathode 170 are connected to the voltage/current source 180 through electrical conductors 190. Tandem OLED 100 is operated by applying an electric potential produced by a voltage/current source 180 between a pair of contact electrodes, anode 110 and cathode 170. Under a forward bias of (V×N), this externally applied electrical potential is distributed among the N EL units and the N−1 intermediate connectors. The electric potential (V×N) across the tandem OLED enables the electrons (negatively charged carriers) to have a potential energy of eV×N (relative to the electrical potential of the anode) when they are injected from the cathode into the N^{th} EL unit. In this N^{th} EL unit, those electrons are transporting onto the LUMO of the LEL before a radiative recombination with the holes (positively charged carriers) on the HOMO of the LEL. During the recombination process, the electrons fall down from the LUMO onto the HOMO of the LEL and lose a portion of their potential energy by producing photons. After the 1^{st} radiative recombination, the electrons are continually transporting from the HOMO of the LEL to the HOMO of the HTL, and then are injected into the (N−1)^{th} intermediate connector. The electrons remain a potential energy of about eV×(N−1) when they are injected from the (N−1)^{th} intermediate connector into the (N−1)^{th} EL unit. This “injection-transport-recombination-transport” process happens in each of the EL units before the electrons eventually are injected into the anode. During the energetically cascading “journey” from the cathode to the anode via the N EL units and the (N−1) intermediate connectors, the electrons can have N times of radiative recombinations to produce photons. In other words, each of the injected electrons from the cathode can have a chance to produce N photons.

Each of the EL units in the tandem OLED 100 is capable of supporting hole injection, hole transport, electron injection, electron transport, and electron-hole recombination to produce light. Each of the EL units can comprise a plurality of layers. Such layers can include a hole-injecting layer (HIL), a hole-transporting layer (HTL), a light-emitting layer (LEL), an electron-transporting layer (ETL), an electron-injecting layer (EIL), hole-blocking layer (HBL), electron-blocking layer (EBL), an exciton-blocking layer (XBL), spacer layers and others known in the art. Various layers can serve multiple functions (e.g., an ETL can also serve as an HBL), and there can be multiple layers that have a similar function (e.g., there can be several LELs, ETLs). There are many organic EL multilayer structures known in the art that can be used as EL units of the present invention. Some non-limiting examples include, HTL/LEL(s)/ETL, HTL/LEL(s)/EIL, HIL/HTL/LEL(s)/ETL, HIL/HTL/LEL(s)/ETL/EIL, HIL/HTL/EBL or XBL/LEL(s)/ETL/EIL, HIL/HTL/LEL(s)/HBL/ETL/EIL. Each of the EL units in the tandem OLED can have the same or different layer structures from other EL units. Preferably, the layer structure of the EL units is of HTL/LEL(s)/ETL, wherein the EL unit adjacent to the anode has a HIL between the anode and the HTL, and wherein the EL unit adjacent to the cathode has an EIL disposed between the cathode and the ETL. Considering the number of the LELs within a specific EL unit, the number of LELs in each of the EL units can be changed typically from 1 to 3. Moreover, each of the EL units in the tandem OLED can emit the same or different color.

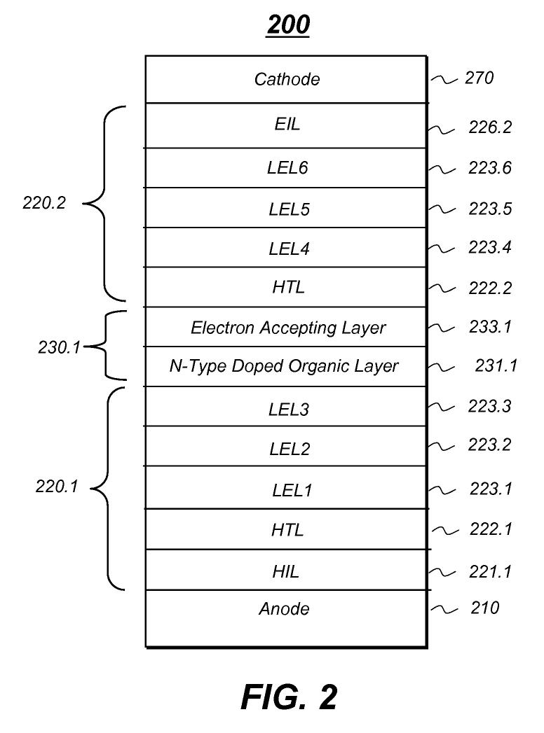

The present invention is more clearly set forth in the embodiment shown in FIG. 2. Tandem OLED device 200 (corresponding to experimental device 1-1) has a first EL unit 220.1 and a second EL unit 220.2 connected in series by intermediate connector 230.1. The first EL unit in this arrangement includes HIL 221.1 (adjacent to the anode 210), HTL 222.1, LELs 223.1, 223.2 and 223.3. The intermediate connector 230.1 includes n-type organic layer 231.1 and electron accepting layer 233.1. A second EL unit 220.2 includes HTL 222.2, LELs 223.4, 223.5 and 223.6, and EIL 226.2. Cathode 270 is provided over EIL 226.2. For clarity, the power supply and electrical conductors are not shown.

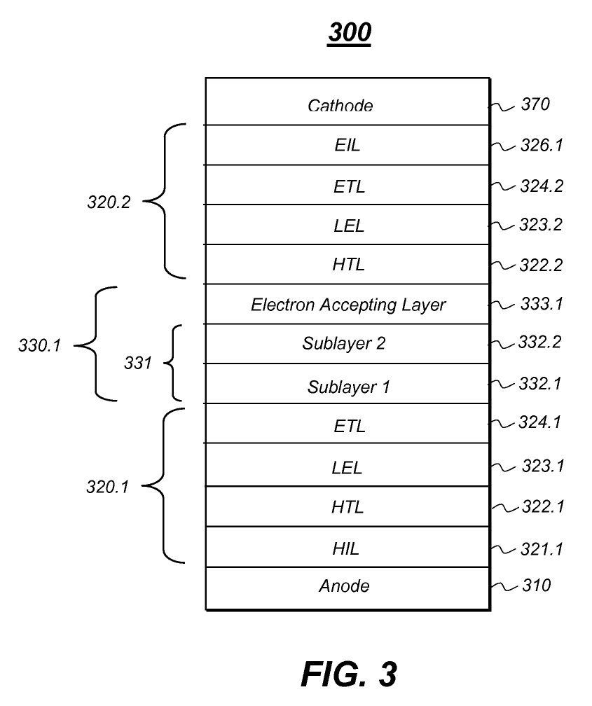

Another embodiment is illustrated in FIG. 3. Tandem OLED device 300 has a first EL unit 320.1 and a second EL unit 320.2 connected in series by intermediate connector 330.1. The first EL unit in this arrangement includes HIL 321.1 (adjacent to the anode 310), HTL 322.1, LEL 323.1 and ETL 324.1. The intermediate connector 330.1 includes n-type organic layer 331 split into two sublayers 332.1 and 332.2 and electron accepting layer 333.1. A second EL unit 320.2 includes HTL 322.2, LEL 323.2, ETL 324.2 and EIL 326.1. Cathode 370 is provided over EIL 326.1. For clarity, the power supply and electrical conductors are not shown.

In another desirable embodiment of the invention, the first and second light-emitting units produce different emission spectra so that overall, the device produces white light. Any combination of two or more separate emissions would be satisfactory. It is preferred that the first light-emitting unit produces light that has multiple peaks at wavelengths longer than 500 nm and substantially no emission at wavelengths shorter than 480 nm, and the second light-emitting unit produces light that has substantial emission at wavelengths shorter than 500 nm.

The critical feature of this invention is that the n-type doped organic layer of the connector contains an organic gallium complex. These complexes have excellent electron-transporting properties.

The organic gallium complex in the n-type doped connector layer is according to Formula (1):

GaL₃ Formula (1)

where the gallium is in a +3 valence state and L represent a monoionic ligand such that the complex has an overall neutral charge. The L groups can be the same or different but at least one must be organic. Desirably, at least two of the L groups are bidentate and contain at least one nitrogen that can form a dative or coordinative bond to the gallium. More preferably, all three ligands are bidentate and contain at least one nitrogen that can form a dative or coordinative bond to the gallium.

The most preferred organic gallium complexes are according to Formula (2):

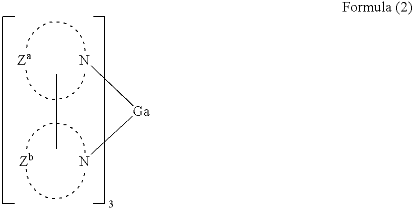

In Formula (2), the ligands in the metal complex can each be the same or different from one another. In one embodiment, the ligands are the same.

Each Z^{a} and Z^{b} is independently selected and represents the atoms necessary to complete an unsaturated heterocyclic ring. For example, Z^{a} and Z^{b} may represent the atoms necessary to complete an unsaturated five- or six-membered heterocyclic ring. In one embodiment, the ring is an aromatic ring. Examples of suitable aromatic rings are a pyridine ring group and an imidazole ring group.

Z^{a} and Z^{b} are directly bonded to one another. In addition to being directly bonded, Z^{a} and Z^{b} may be further linked together to form a fused ring system. However, in one embodiment, Z^{a} and Z^{b} are not further linked together.

Illustrative examples of Z^{a} and Z^{b} are shown below.

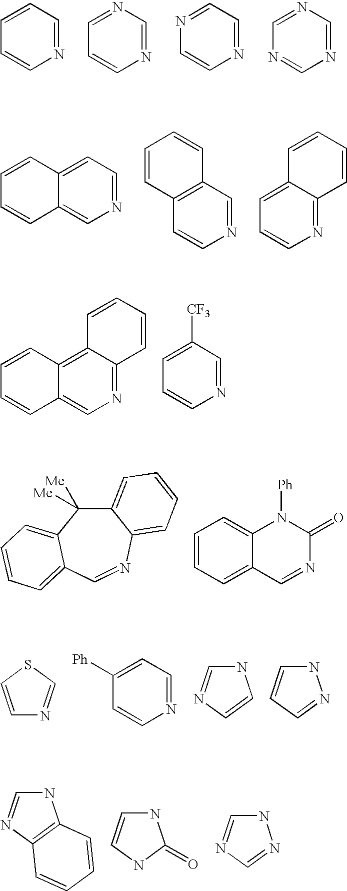

In Formula (2), the gallium bond to the nitrogen of one heterocycle is an ionic bond. An ionic bond is an electrical attraction between two oppositely charged atoms or groups of atoms. In this case, the metal is positively charged and one nitrogen of one heterocycle is negatively charged and the gallium and this nitrogen are bonded together. However, it should be understood that this bond could have some covalent character, depending on the particular metal and heterocycle. By way of example, a deprotonated imidazole would be capable of forming an ionic bond of this type with the metal.

In Formula (2), the gallium bond to the nitrogen of the other heterocycle is dative. A dative bond (also called a donor/acceptor bond) is a bond involving a shared pair of electrons in which both electrons come from the same atom, in this case, the nitrogen of the heterocycle. For example, a pyridine has a nitrogen with two unshared electrons that can be donated to the metal to form a dative bond.

In one aspect of the invention, the metal complex is represented by Formula (3).

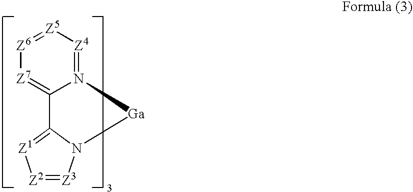

Each Z¹ through Z⁷ represents N or C—Y. In one embodiment, no more than two, and desirably no more than one of Z¹ to Z³ represent N. In another embodiment, no more than one of Z⁴ to Z⁷ represents N. Each Y represents hydrogen or an independently selected substituent. Examples of substituents include an alkyl group such as methyl group, an aromatic group such as a phenyl group, a cyano substituent, and a trifluoromethyl group. Two Y substituents may join to form a ring group, for example a fused benzene ring group. In one aspect of the invention, Z⁴ through Z⁷ represent C—Y.

Illustrative examples of organic gallium complexes of Formula (1) are given below.

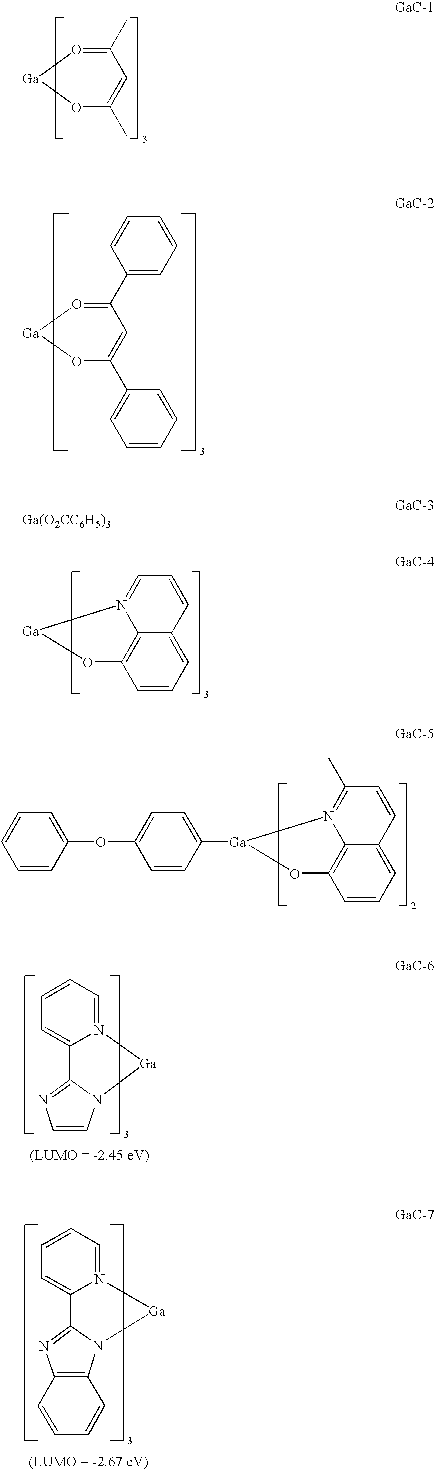

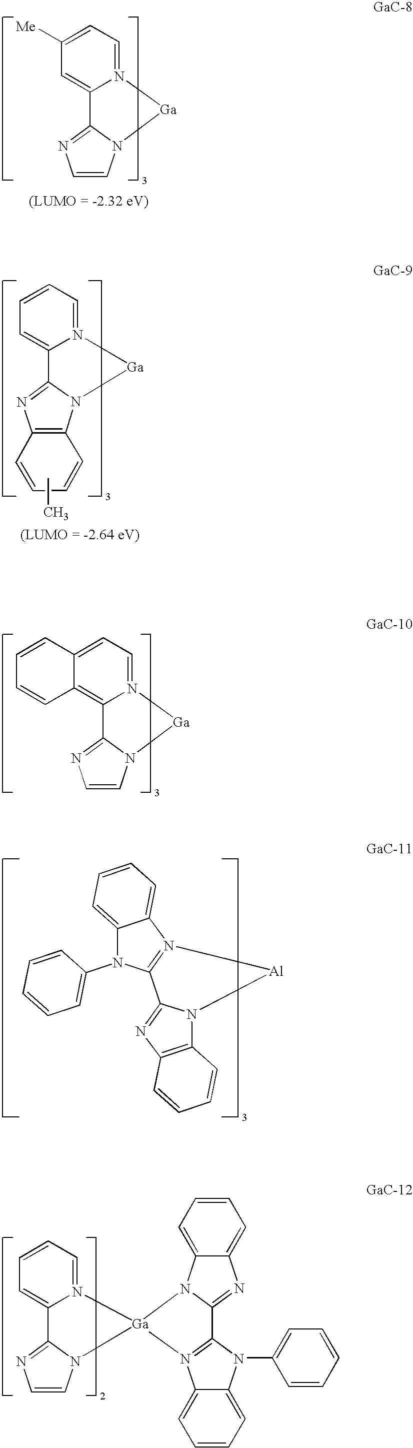

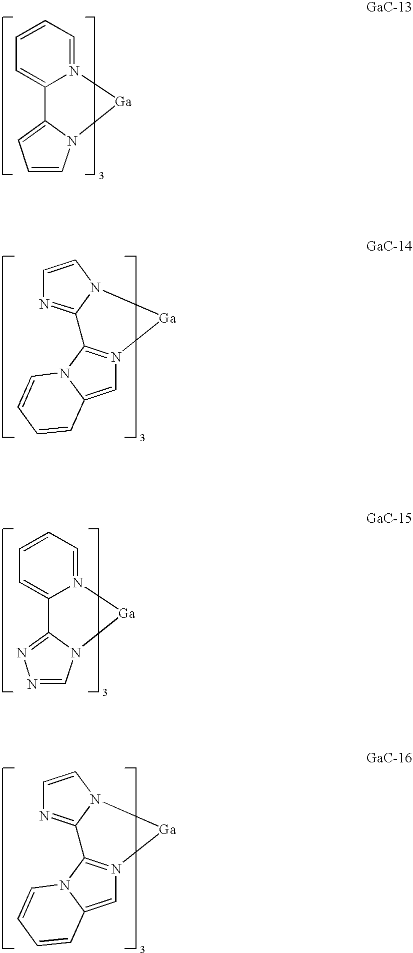

The organic gallium complexes of this invention are prepared as known in the art; for example, see US App 20070003786 and U.S. Pat. No. 6,001,284.

The n-type doped organic layer contains at least one organic gallium complex as a host and at least one n-type dopant. The term “n-type doped organic layer” means that this layer has semiconducting properties after doping, and the electrical current through this layer is substantially carried by the electrons. There may be more than one host material present. A host material is capable of supporting electron injection and electron transport.

Any of the electron-transporting materials defined for use in the ETL represent a useful class of co-host material in addition to the organic gallium complex for the n-type doped organic layer. Particular examples of co-host materials are metal chelated oxinoid compounds, including chelates of oxine itself (also commonly referred to as 8-quinolinol or 8-hydroxyquinoline), such as tris(8-hydroxyquinoline)aluminum (Alq). Other materials include various butadiene derivatives as disclosed by Tang in U.S. Pat. No. 4,356,429, various heterocyclic optical brighteners as disclosed by VanSlyke et al. in U.S. Pat. No. 4,539,507, triazines, hydroxyquinoline derivatives, benzazole derivatives, and phenanthroline derivatives. Silole derivatives, such as 2,5-bis(2′,2″-bipridin-6-yl)-1,1-dimethyl-3,4-diphenyl silacyclopentadiene are also useful host organic materials. More preferred examples of useful host materials in the n-type organic doped layer include Alq, 4,7-diphenyl-1,10-phenanthroline (Bphen), 2,9-dimethyl-4,7-diphenyl-1,10-phenanthroline (BCP), or 2,2′-[1,1′-biphenyl]-4,4′-diylbis[4,6-(p-tolyl)-1,3,5-triazine](TRAZ), or combinations thereof. Phenanthrolines such as Bphen or BCP are particularly preferred.

The n-type dopant in the n-type doped organic layer includes alkali metals, alkali metal compounds, alkaline earth metals, or alkaline earth metal compounds, or combinations thereof. The term “metal compounds” includes organometallic complexes, metal-organic salts, and inorganic salts, oxides and halides. Among the class of metal-containing n-type dopants, includes Li, Na, K, Rb, Cs, Mg, Ca, Sr, Ba, La, Ce, Nd, Sm, Eu, Tb, Dy, or Yb, or combinations thereof and their compounds, are particularly useful. Of these, lithium is most preferred. The materials used as the n-type dopants in the n-type doped organic layer also include organic reducing agents with strong electron-donating properties. By “strong electron-donating properties” it is meant that the organic dopant should be able to donate at least some electronic charge to the host to form a charge-transfer complex with the host. Nonlimiting examples of organic molecules include bis(ethylenedithio)-tetrathiafulvalene (BEDT-TTF), tetrathiafulvalene (TTF), and their derivatives. In the case of polymeric hosts, the dopant can be any of the above or also a material molecularly dispersed or copolymerized with the host as a minor component. The n-type doped concentration is preferably in the range of 0.01-20% by volume. The thickness of the n-type doped organic layer is typically less than 200 nm, and preferably less than 100 nm and greater than 3 nm.

In one embodiment of this invention, the n-type layer is divided into two sublayers (as illustrated in FIG. 3 as 331.1 and 331.2) that are in contact with each other and one of which (331.1) is in contact with the second light emitting unit. The sublayer 331.2 that contacts the electron accepting layer and is furthest away from the second light emitting unit must always contain the organic gallium complex, while the sublayer closest to the second light emitting unit may optionally contain an organic gallium complex which may be the same or different. It is also desirable that the sublayer in contact with the second light emitting unit includes a material that has a LUMO energy level less negative than the LUMO energy level of the primary host material in the closest light emitting layer of the second light emitting unit. It is also desirable that the energy level of the material in the sublayer in contact with the second light emitting unit is the same or less negative than the gallium complex in the other sublayer. It is preferred that this material in the sublayer closest to the second light emitting layer be an organic gallium complex, which may be the same or different as the organic gallium complex in the other sublayer. It is also preferred that both sublayers contain a n-type dopant. A primary host material is the host material that in present in the light emitting layer in the largest amount by % volume. If two (or more) hosts are present at identical amounts, then the one with the highest (least negative) LUMO energy level is considered the primary host. LUMO energy levels can be calculated by any of the methods as well known in the art.

The electron-accepting layer of the intermediate connector includes one or more organic materials, each having an electron-accepting property and suitably, a reduction potential greater than −0.5 V vs. a Saturated Calomel Electrode (SCE), and wherein the one or more organic materials provide more than 50% by volume in the intermediate connector. Preferably, the electron-accepting layer includes one or more organic materials having a reduction potential greater than −0.1 V vs. SCE. More preferably, the electron-accepting layer includes a single organic material having an electron-accepting property and a reduction potential greater than −0.1 V vs. SCE. By “electron-accepting property” it is meant that the organic material has the capability or tendency to accept at least some electronic charge from other type of material that it is adjacent.

The term “reduction potential”, expressed in volts, measures the affinity of a substance for an electron, the higher the positive number the greater the affinity. Reduction of hydronium ions into hydrogen gas would have a reduction potential of 0.00 V under standard conditions. The reduction potential of a substance can be conveniently obtained by cyclic voltammetry (CV) and it is measured vs. SCE. The measurement of the reduction potential of a substance can be as following: A Model CHI660 electrochemical analyzer (CH Instruments, Inc., Austin, Tex.) is employed to carry out the electrochemical measurements. Both CV and Osteryoung square-wave voltammetry (SWV) can be used to characterize the redox properties of the substance. A glassy carbon (GC) disk electrode (A=0.071 cm²) is used as working electrode. The GC electrode is polished with 0.05 μm alumina slurry, followed by sonication cleaning in deionized water twice and rinsed with acetone in between water cleaning. The electrode is finally cleaned and activated by electrochemical treatment prior to use. A platinum wire can be used as the counter electrode and the SCE is used as a quasi-reference electrode to complete a standard 3-electrode electrochemical cell. A mixture of acetonitrile and toluene (1:1 MeCN/toluene) or methylene chloride (MeCl₂) can be used as organic solvent systems. All solvents used are ultra low water grade (<10 ppm water). The supporting electrolyte, tetrabutylammonium tetrafluoroborate (TBAF) is recrystallized twice in isopropanol and dried under vacuum for three days. Ferrocene (Fc) can be used as an internal standard (E^{red}_{Fc}=0.50 V vs. SCE in 1:1 MeCN/toluene, E^{red}_{Fc}=0.55 V vs. SCE in MeCl₂, 0.1 M TBAF). The testing solution is purged with high purity nitrogen gas for approximately 15 minutes to remove oxygen and a nitrogen blanket is kept on the top of the solution during the course of the experiments. All measurements are performed at ambient temperature of 25±1° C. If the compound of interest has insufficient solubility, other solvents can be selected and used by those skilled in the art. Alternatively, if a suitable solvent system cannot be identified, the electron-accepting material can be deposited onto the electrode and the reduction potential of the modified electrode can be measured.

The electron-accepting layer, including one or more organic materials suitably having a reduction potential greater than −0.5 V vs. SCE and providing more than 50% by volume in the electron-accepting layer, can have both effective carrier injection and effective optical transparency in the tandem OLED. Organic materials suitable for use in the electron-accepting layer include not only simple compounds containing at least carbon and hydrogen, but also include metal complexes, e.g., transition metal complexes having organic ligands and organometallic compounds, preferably as long as their reduction potentials are more positive than −0.5 V vs. SCE. Organic materials for the electron-accepting layer can include small molecules (capable of being deposited by vapor deposition), polymers, or dendrimers, or combinations thereof. It is also important that at least a portion of the electron-accepting layer does not significantly mix with adjacent layers. This can be accomplished by choosing materials having molecular weight high enough to prevent such diffusion. Preferably, the molecular weight of the electron-accepting material is greater than 350. To maintain the proper electron-accepting properties of the layer, it is desirable that the one or more organic materials constitute more than 90% by volume of the electron-accepting layer. For manufacturing simplicity, a single compound can be used for the electron-accepting layer.

Among suitable materials for the electron accepting layer of the connector includes oxidizing agents with strong electron-withdrawing properties. “Strong electron-withdrawing properties” means that the organic dopant should be able to accept some electronic charge from the host to form a charge-transfer complex with the host material. Some nonlimiting examples include organic compounds such as 2,3,5,6-tetrafluoro-7,7,8,8-tetracyanoquinodimethane (F₄-TCNQ; E_{red}=+0.643) and other derivatives of 7,7,8,8-tetracyanoquinodimethane (TCNQ; E_{red}=+0.167). In addition, any of the hole-transporting materials defined for use in the HIL represent useful classes of materials for this application.

In particular, hexaazatriphenylene derivatives, as described in U.S. Pat. No. 6,720,573, US App 2004113547 and US App 2005255334 are very desirable for use in an electron accepting layer. A structural formula for a desirable class of hexaazatriphenylene is according to Formula (HATP):

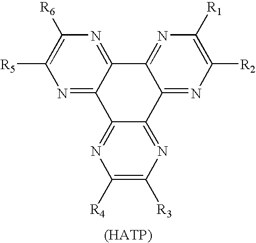

where R₁-R₆ are independently chosen hydrogen or a substituent. Preferred substituents are those that are more electron-withdrawing than hydrogen and most preferred are cyano. For CHATP where R₁-R₆ are all cyano groups, the E_{red} is −0.08.

The thickness of the p-type doped organic layer is typically less than 150 nm, and preferably in the range of about 3 to 100 nm.

A p-type doped organic layer can form at the interface of the electron-accepting layer and the HTL simply by deposition of the HTL material. In this invention, the materials chosen for the electron-accepting layer and the HTL are such that only a small amount of mixing occurs. That is, it is important that at least some of the electron-accepting layer does not mix with the HTL material.

The host materials used in the intermediate connectors can comprise small molecule materials or polymeric materials, or combinations thereof. In some instances, the same host material can be used for both n-type and electron accepting layers, provided that it exhibits both hole and electron transport properties set forth above. Examples of materials that can be used as host for either the n-type doped organic layer or electron accepting layer include, but are not limited to, various anthracene derivatives as described in U.S. Pat. No. 5,972,247, certain carbazole derivatives such as 4,4-bis(9-dicarbazolyl)-biphenyl (CBP), and distyrylarylene derivatives such as 4,4′-bis(2,2′-diphenyl vinyl)-1,1′-biphenyl, and as described in U.S. Pat. No. 5,121,029.

The overall thickness (combination of the n-type doped organic layer and the electron accepting layer) of an intermediate connector is typically from 5 nm to 200 nm. If there are more than two intermediate connectors in a tandem OLED, the intermediate connectors can be the same or different from each other in terms of layer thickness, material selection, or both.

The following is the description of the layer structure, material selection, and fabrication process for OLED devices.

The present invention can be employed in many OLED configurations using small molecule materials, oligomeric materials, polymeric materials, or combinations thereof. These include from very simple structures having a single anode and cathode to more complex devices, such as passive matrix displays having orthogonal arrays of anodes and cathodes to form pixels, and active-matrix displays where each pixel is controlled independently, for example, with thin film transistors (TFTs). There are numerous configurations of the organic layers wherein the present invention is successfully practiced. For this invention, essential requirements are a cathode, an anode, two LELs with a connecting unit comprising a n-type doped organic layer and an electron accepting layer.

Also, the total combined thickness of the organic layers is preferably less than 500 nm for each separate light emitting unit. The overall total thickness of the stacked OLED device will depend on the number of separate light emitting and connecting units used.

Enhanced device stability can sometimes be achieved when the OLED is operated in an AC mode where, for some time period in cycle, the potential bias is reversed and no current flows. An example of an AC driven OLED is described in U.S. Pat. No. 5,552,678.

The OLED device can have a microcavity structure. In one useful example, one of the metallic electrodes is essentially opaque and reflective; the other one is reflective and semitransparent. The reflective electrode is preferably selected from Au, Ag, Mg, Ca, or alloys thereof. Because of the presence of the two reflecting metal electrodes, the device has a microcavity structure. The strong optical interference in this structure results in a resonance condition. Emission near the resonance wavelength is enhanced and emission away from the resonance wavelength is depressed. The optical path length can be tuned by selecting the thickness of the organic layers or by placing a transparent optical spacer between the electrodes. For example, an OLED device of this invention can have ITO spacer layer placed between a reflective anode and the organic EL media, with a semitransparent cathode over the organic EL media.

When the desired EL emission is viewed through the anode, anode 110 should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode 110. For applications where EL emission is viewed only through the cathode 170, the transmissive characteristics of the anode 110 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize short circuits or enhance reflectivity.

Although it is not always necessary, it is often useful to provide an HIL in the OLEDs. HILs in the OLEDs can serve to facilitate hole injection from the anode into the HTL, thereby reducing the drive voltage of the OLEDs. Suitable materials for use in the hole-injecting layer include, but are not limited to, porphyrinic compounds as described in U.S. Pat. No. 4,720,432, plasma-deposited fluorocarbon polymers as described in U.S. Pat. Nos. 6,127,004, 6,208,075, and 6,208,077, some aromatic amines, for example, m-MTDATA (4,4′,4″-tris[(3-methylphenyl)phenyl-amino]triphenylamine), and inorganic oxides including vanadium oxide (VOx), molybdenum oxide (MoOx), and nickel oxide (NiOx). Alternative hole-injecting materials reportedly useful in OLEDs are described in EP 0 891 121 A1 and EP 1 029 909 A1. The aromatic tertiary amines discussed below can also be useful as hole-injecting materials. Other useful hole-injecting materials such as dipyrazino[2,3-f:2′,3′-h]quinoxalinehexacarbonitrile are described in U.S. Patent Application Publication 2004/0113547 A1 and U.S. Pat. No. 6,720,573. In addition, a p-type doped organic layer is also useful for the HIL as described in U.S. Pat. No. 6,423,429. The term “p-type doped organic layer” means that this layer has semiconducting properties after doping, and the electrical current through this layer is substantially carried by the holes. The conductivity is provided by the formation of a charge-transfer complex as a result of hole transfer from the dopant to the host material.

The thickness of the HIL is in the range of from 0.1 nm to 200 nm, preferably, in the range of from 0.5 nm to 150 nm.

The HTL contains at least one hole-transporting material such as an aromatic tertiary amine, where the latter is understood to be a compound containing at least one trivalent nitrogen atom that is bonded only to carbon atoms, at least one of which is a member of an aromatic ring. In one form the aromatic tertiary amine is an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals or at least one active hydrogen-containing group are disclosed by Brantley, et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula (A)

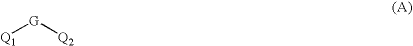

wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula (B)

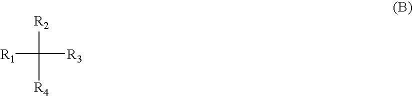

wherein:

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural Formula (C)

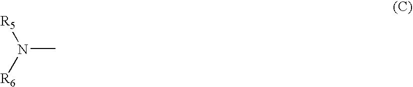

wherein:

R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula (C), linked through an arylene group. Useful tetraaryldiamines include those represented by Formula (D)

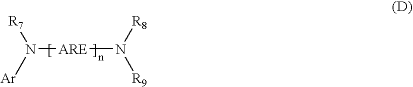

wherein:

each ARE is an independently selected arylene group, such as a phenylene or anthracene moiety;

n is an integer of from 1 to 4; and

Ar, R₇, R₈, and R₉ are independently selected aryl groups.

In a typical embodiment, at least one of Ar, R₇, R₈, and R₉ is a polycyclic fused ring structure, e.g., a naphthalene.

Another class of the hole-transporting material comprises a material of formula (E):

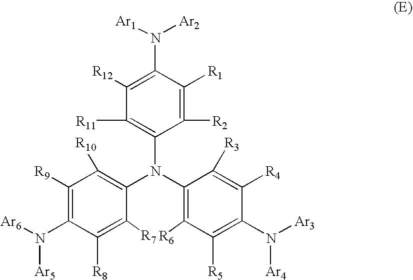

In formula (E), Ar₁-Ar₆ independently represent aromatic groups, for example, phenyl groups or tolyl groups;

R₁-R₁₂ independently represent hydrogen or independently selected substituent, for example an alkyl group containing from 1 to 4 carbon atoms, an aryl group, a substituted aryl group.

The various alkyl, alkylene, aryl, and arylene moieties of the foregoing structural Formulae (A), (B), (C), (D), and (E) can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms, e.g. cyclopentyl, cyclohexyl, and cycloheptyl ring structures. The aryl and arylene moieties are typically phenyl and phenylene moieties.

The HTL is formed of a single or a mixture of aromatic tertiary amine compounds. Specifically, one can employ a triarylamine, such as a triarylamine satisfying the Formula (B), in combination with a tetraaryldiamine, such as indicated by Formula (D). When a triarylamine is employed in combination with a tetraaryldiamine, the latter is positioned as a layer interposed between the triarylamine and the electron injecting and transporting layer. Aromatic tertiary amines are useful as hole-injecting materials also. Illustrative of useful aromatic tertiary amines are the following:

1,1-bis(4-di-p-tolylaminophenyl)cyclohexane;

1,1-bis(4-di-p-tolylaminophenyl)-4-phenylcyclohexane;

1,5-bis[N-(1-naphthyl)-N-phenylamino]naphthalene;

2,6-bis(di-p-tolylamino)naphthalene;

2,6-bis[di-(1-naphthyl)amino]naphthalene;

2,6-bis[N-(1-naphthyl)-N-(2-naphthyl)amino]naphthalene;

2,6-bis[N,N-di(2-naphthyl)amine]fluorene;

4-(di-p-tolylamino)-4′-[4(di-p-tolylamino)-styryl]stilbene;

4,4′-bis(diphenylamino)quadriphenyl;

4,4″-bis[N-(1-anthryl)-N-phenylamino]-p-terphenyl;

4,4′-bis[N-(1-coronenyl)-N-phenylamino]biphenyl;

4,4′-bis[N-(1-naphthyl)-N-phenylamino]biphenyl (NPB);

4,4′-bis[N-(1-naphthyl)-N-(2-naphthyl)amino]biphenyl (TNB);

4,4″-bis[N-(1-naphthyl)-N-phenylamino]p-terphenyl;

4,4′-bis[N-(2-naphthacenyl)-N-phenylamino]biphenyl;

4,4′-bis[N-(2-naphthyl)-N-phenylamino]biphenyl;

4,4′-bis[N-(2-perylenyl)-N-phenylamino]biphenyl;

4,4′-bis[N-(2-phenanthryl)-N-phenylamino]biphenyl;

4,4′-bis[N-(2-pyrenyl)-N-phenylamino]biphenyl;

4,4′-bis[N-(3-acenaphthenyl)-N-phenylamino]biphenyl;

4,4′-bis[N-(3-methylphenyl)-N-phenylamino]biphenyl (TPD);

4,4′-bis[N-(8-fluoranthenyl)-N-phenylamino]biphenyl;

4,4′-bis[N-(9-anthryl)-N-phenylamino]biphenyl;

4,4′-bis{N-phenyl-N-[4-(1-naphthyl)-phenyl]amino }biphenyl;

4,4′-bis[N-phenyl-N-(2-pyrenyl)amino]biphenyl;

4,4′,4″-tris[(3-methylphenyl)phenylamino]triphenylamine (m-TDATA);

Bis(4-dimethylamino-2-methylphenyl)-phenylmethane;

N-phenylcarbazole;

N,N′-bis[4-([1,1′-biphenyl]-4-ylphenylamino)phenyl]-N,N′-di-1-naphthalenyl-[1,1′-biphenyl]-4,4′-diamine;

N,N′-bis[4-(di-1-naphthalenylamino)phenyl]-N,N′-di-1-naphthalenyl-[1,1′-biphenyl]-4,4′-diamine;

N,N′-bis[4-[(3-methylphenyl)phenylamino]phenyl]-N,N′-diphenyl-[1,1′-biphenyl]-4,4′-diamine;

N,N-bis[4-(diphenylamino)phenyl]-N′,N′-diphenyl-[1,1′-biphenyl]-4,4′-diamine;

N,N′-di-1-naphthalenyl-N,N′-bis[4-(1-naphthalenylphenylamino)phenyl]-[1,1′-biphenyl]-4,4′-diamine;

N,N′-di-1-naphthalenyl-N,N′-bis[4-(2-naphthalenylphenylamino)phenyl]-[1,1′-biphenyl]-4,4′-diamine;

N,N,N-tri(p-tolyl)amine;

N,N,N′,N′-tetra-p-tolyl-4-4′-diaminobiphenyl;

N,N,N′,N′-tetraphenyl-4,4′-diaminobiphenyl;

N,N,N′,N′-tetra-1-naphthyl-4,4′-diaminobiphenyl;

N,N,N′,N′-tetra-2-naphthyl-4,4′-diaminobiphenyl; and

N,N,N′,N′-tetra(2-naphthyl)-4,4″-diamino-p-terphenyl.

Another class of useful hole-transporting materials includes polycyclic aromatic compounds as described in EP 1 009 041. Tertiary aromatic amines with more than two amine groups can be used including oligomeric materials. In addition, polymeric hole-transporting materials are used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

The thickness of the HTL is in the range of from 5 nm to 200 nm, preferably, in the range of from 10 nm to 150 nm.

An optional exciton- or electron-blocking layer may be present between the HTL and the LEL. These are particularly useful when the LEL uses a phosphorescent or triplet emitter. Some suitable examples of such blocking layers are described in U.S. App 20060134460 A1.

As more fully described in U.S. Pat. Nos. 4,769,292 and 5,935,721, the light-emitting layer(s) (LEL) of the organic EL elements shown in FIG. 1 comprises a luminescent, fluorescent or phosphorescent material where electroluminescence is produced as a result of electron-hole pair recombination in this region. The light-emitting layer can be comprised of a single material, but more commonly consists of non-electroluminescent compounds (generally referred to as the host) doped with an electroluminescent guest compound (generally referred to as the dopant) or compounds where light emission comes primarily from the electroluminescent compound and can be of any color. Electroluminescent compounds can be coated as 0.01 to 50% into the non-electroluminescent component material, but typically coated as 0.01 to 30% and more typically coated as 0.01 to 15% into the non-electroluminescent component. The thickness of an individual LEL can be any suitable thickness. It can be in the range of from 0.1 mm to 100 mm.

An important relationship for choosing a dye as a electroluminescent component is a comparison of the bandgap potential which is defined as the energy difference between the highest occupied molecular orbital and the lowest unoccupied molecular orbital of the molecule. For efficient energy transfer from the non-electroluminescent compound to the electroluminescent compound molecule, a necessary condition is that the band gap of the electroluminescent compound is smaller than that of the non-electroluminescent compound or compounds. Thus, the selection of an appropriate host material is based on its electronic characteristics relative to the electronic characteristics of the electroluminescent compound, which itself is chosen for the nature and efficiency of the light emitted. As described below, fluorescent and phosphorescent dopants typically have different electronic characteristics so that the most appropriate hosts for each may be different. However in some cases, the same host material can be useful for either type of dopant.

Non-electroluminescent compounds and emitting molecules known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

### a) Phosphorescent Light Emitting Layers

Suitable hosts for phosphorescent LELs should be selected so that transfer of a triplet exciton can occur efficiently from the host to the phosphorescent dopant(s) but cannot occur efficiently from the phosphorescent dopant(s) to the host. Therefore, it is highly desirable that the triplet energy of the host be higher than the triplet energies of phosphorescent dopant. Generally speaking, a large triplet energy implies a large optical band gap. However, the band gap of the host should not be chosen so large as to cause an unacceptable barrier to injection of holes into the fluorescent blue LEL and an unacceptable increase in the drive voltage of the OLED. The host in a phosphorescent LEL may include any of the aforementioned hole-transporting material used for the HTL, as long as it has a triplet energy higher than that of the phosphorescent dopant in the layer. The host used in a phosphorescent LEL can be the same as or different from the hole-transporting material used in the HTL. In some cases, the host in the phosphorescent LEL may also suitably include an electron-transporting material (it will be discussed thereafter), as long as it has a triplet energy higher than that of the phosphorescent dopant.

In addition to the aforementioned hole-transporting materials in the HTL, there are several other classes of hole-transporting materials suitable for use as the host in a phosphorescent LEL.

One desirable host comprises a hole-transporting material of formula (F):

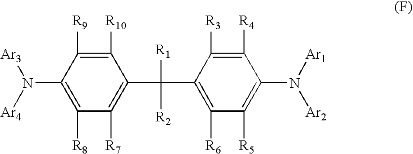

In formula (F), R₁ and R₂ represent substituents, provided that R₁ and R₂ can join to form a ring. For example, R₁ and R₂ can be methyl groups or join to form a cyclohexyl ring;

Ar₁-Ar₄ represent independently selected aromatic groups, for example phenyl groups or tolyl groups;

R₃-R₁₀ independently represent hydrogen, alkyl, substituted alkyl, aryl, substituted aryl group.

Examples of suitable materials include, but are not limited to:

1,1-Bis(4-(N,N-di-p-tolylamino)phenyl)cyclohexane (TAPC);

1,1-Bis(4-(N,N-di-p-tolylamino)phenyl)cyclopentane;

4,4′-(9H-fluoren-9-ylidene)bis[N,N-bis(4-methylphenyl)-benzenamine;

1,1-Bis(4-(N,N-di-p-tolylamino)phenyl)-4-phenylcyclohexane;

1,1-Bis(4-(N,N-di-p-tolylamino)phenyl)-4-methylcyclohexane;

1,1-Bis(4-(N,N-di-p-tolylamino)phenyl)-3-phenylpropane;

Bis[4-(N,N-diethylamino)-2-methylphenyl](4-methylpenyl)methane;

Bis[4-(N,N-diethylamino)-2-methylphenyl](4-methylphenyl)ethane;

4-(4-Diethylaminophenyl)triphenylmethane;

4,4′-Bis(4-diethylaminophenyl)diphenylmethane.

A useful class of triarylamines suitable for use as the host includes carbazole derivatives such as those represented by formula (G):

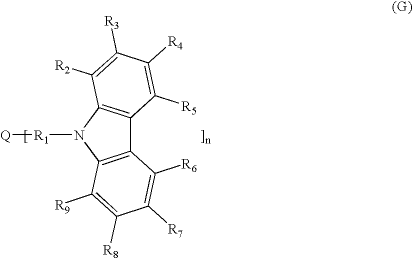

In formula (G), Q independently represents nitrogen, carbon, an aryl group, or substituted aryl group, preferably a phenyl group;

R₁ is preferably an aryl or substituted aryl group, and more preferably a phenyl group, substituted phenyl, biphenyl, substituted biphenyl group;

R₂ through R₇ are independently hydrogen, alkyl, phenyl or substituted phenyl group, aryl amine, carbazole, or substituted carbazole;

and n is selected from 1 to 4.

Another useful class of carbazoles satisfying structural formula (G) is represented by formula (H):

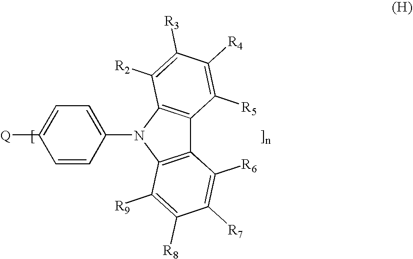

wherein:

n is an integer from 1 to 4;

Q is nitrogen, carbon, an aryl, or substituted aryl;

R₂ through R₇ are independently hydrogen, an alkyl group, phenyl or substituted phenyl, an aryl amine, a carbazole and substituted carbazole.

Illustrative of useful substituted carbazoles are the following:

4-(9H-carbazol-9-yl)-N,N-bis[4-(9H-carbazol-9-yl)phenyl]-benzenamine (TCTA);

4-(3-phenyl-9H-carbazol-9-yl)-N,N-bis[4(3-phenyl-9H-carbazol-9-yl)phenyl]-benzenamine;

9,9′-[5′-[4-(9H-carbazol-9-yl)phenyl][1,1′:3′,1″-terphenyl]-4,4″-diyl]bis-9H-carbazole.
9,9′-(2,2′-dimethyl[1,1′-biphenyl]-4,4′-diyl)bis-9H-carbazole (CDBP);

9,9′-[1,1′-biphenyl]-4,4′-diylbis-9H-carbazole (CBP);

9,9′-(1,3-phenylene)bis-9H-carbazole (mCP);

9,9′-(1,4-phenylene)bis-9H-carbazole;

9,9′,9″-(1,3,5-benzenetriyl)tris-9H-carbazole;

9,9′-(1,4-phenylene)bis[N,N,N′,N′-tetraphenyl-9H-carbazole-3,6-diamine;

9[4-(9H-carbazol-9-yl)phenyl]-N,N-diphenyl-9H-carbazol-3-amine;

9,9′-(1,4-phenylene)bis[N,N-diphenyl-9H-carbazol-3-amine;

9-[4-(9H-carbazol-9-yl)phenyl]-N,N,N′,N′-tetraphenyl-9H-carbazole-3,6-diamine.

The above classes of hosts suitable for phosphorescent LELs may also be used as hosts in fluorescent LELs as well.

Suitable phosphorescent dopants for use in a phosphorescent LEL can be selected from the phosphorescent materials described by formula (J) below:

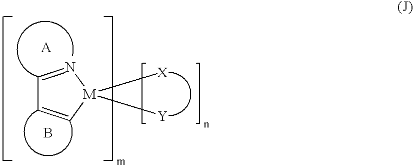

wherein:

A is a substituted or unsubstituted heterocyclic ring containing at least one nitrogen atom;

B is a substituted or unsubstituted aromatic or heteroaromatic ring, or ring containing a vinyl carbon bonded to M;

X—Y is an anionic bidentate ligand;

m is an integer from 1 to 3 and

n in an integer from 0 to 2 such that m+n=3 for M=Rh or Ir; or

m is an integer from 1 to 2 and n in an integer from 0 to 1 such that

m+n=2 for M=Pt or Pd.

Compounds according to formula (J) may be referred to as C,N— (or ĈN—) cyclometallated complexes to indicate that the central metal atom is contained in a cyclic unit formed by bonding the metal atom to carbon and nitrogen atoms of one or more ligands. Examples of heterocyclic ring A in formula (J) include substituted or unsubstituted pyridine, quinoline, isoquinoline, pyrimidine, indole, indazole, thiazole, and oxazole rings. Examples of ring B in formula (J) include substituted or unsubstituted phenyl, napthyl, thienyl, benzothienyl, furanyl rings. Ring B in formula (J) may also be a N-containing ring such as pyridine, with the proviso that the N-containing ring bonds to M through a C atom as shown in formula (J) and not the N atom.

An example of a tris-C,N-cyclometallated complex according to formula (J) with m=3 and n=0 is tris(2-phenyl-pyridinato-N,C^{2′}-)Iridium (III), shown below in stereodiagrams as facial (fac-) or meridional (mer-) isomers.

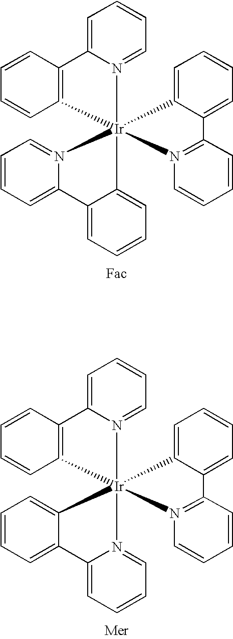

Generally, facial isomers are preferred since they are often found to have higher phosphorescent quantum yields than the meridional isomers. Additional examples of tris-C,N-cyclometallated phosphorescent materials according to formula (J) are tris(2-(4′-methylphenyl)pyridinato-N,C^{2′})Iridium(III), tris(3-phenylisoquinolinato-N,C^{2′})Iridium(III), tris(2-phenylquinolinato-N,C^{2′})Iridium(III), tris(1-phenylisoquinolinato-N,C^{2′})Iridium(III), tris(1-(4′-methylphenyl)isoquinolinato-N,C^{2′})Iridium(III), tris(2-(4′,6′-diflourophenyl)-pyridinato-N,C^{2′})Iridium(III), tris(2-((5′-phenyl)-phenyl)pyridinato-N,C^{2′})Iridium(III), tris(2-(2′-benzothienyl)pyridinato-N,C^{3′})Iridium(III), tris(2-phenyl-3,3′dimethyl)indolato-N,C^{2′})Ir(III), tris(1-phenyl-1H-indazolato-N,C^{2′})Ir(III).
Of these, tris(1-phenylisoquinoline) iridium (III) (also referred to as Ir(piq)₃) and tris(2-phenylpyridine) iridium (also referred to as Ir(ppy)₃) are particularly suitable for this invention.

Tris-C,N-cyclometallated phosphorescent materials also include compounds according to formula (J) wherein the monoanionic bidentate ligand X—Y is another C,N-cyclometallating ligand. Examples include bis(1-phenylisoquinolinato-N,C^{2′})(2-phenylpyridinato-N,C^{2′})Iridium(III) and bis(2-phenylpyridinato-N,C^{2′})(1-phenylisoquinolinato-N,C^{2′})Iridium(III). Synthesis of such tris-C,N-cyclometallated complexes containing two different C,N-cyclometallating ligands may be conveniently synthesized by the following steps. First, a bis-C,N-cyclometallated diiridium dihalide complex (or analogous dirhodium complex) is made according to the method of Nonoyama (Bull. Chem. Soc. Jpn., 47, 767 (1974)). Secondly, a zinc complex of the second, dissimilar C,N-cyclometallating ligand is prepared by reaction of a zinc halide with a lithium complex or Grignard reagent of the cyclometallating ligand. Third, the thus formed zinc complex of the second C,N-cyclometallating ligand is reacted with the previously obtained bis-C,N-cyclometallated diiridium dihalide complex to form a tris-C,N-cyclometallated complex containing the two different C,N-cyclometallating ligands. Desirably, the thus obtained tris-C,N-cyclometallated complex containing the two different C,N-cyclometallating ligands may be converted to an isomer wherein the C atoms bonded to the metal (e.g. Ir) are all mutually cis by heating in a suitable solvent such as dimethyl sulfoxide.

Suitable phosphorescent materials according to formula (J) may in addition to the C,N-cyclometallating ligand(s) also contain monoanionic bidentate ligand(s) X—Y that are not C,N-cyclometallating. Common examples are beta-diketonates such as acetylacetonate, and Schiff bases such as picolinate. Examples of such mixed ligand complexes according to formula (J) include bis(2-phenylpyridinato-N,C^{2′})Iridium(III)(acetylacetonate), bis(2-(2′-benzothienyl)pyridinato-N,C^{3′})Iridium(III)(acetylacetonate), and bis(2-(4′,6′-diflourophenyl)-pyridinato-N,C^{2′})Iridium(III)(picolinate). Other important phosphorescent materials according to formula (J) include C,N-cyclometallated Pt(II) complexes such as cis-bis(2-phenylpyridinato-N,C^{2′})platinum(II), cis-bis(2-(2′-thienyl)pyridinato-N,C^{3′})platinum(II), cis-bis(2-(2′-thienyl)quinolinato-N,C^{5′})platinum(II), or (2-(4′,6′-difluorophenyl)pyridinato-N,C^{2′})platinum (II) (acetylacetonate).

The emission wavelengths (color) of C,N-cyclometallated phosphorescent materials according to formula (J) are governed principally by the lowest energy optical transition of the complex and hence by the choice of the C,N-cyclometallating ligand. For example, 2-phenyl-pyridinato-N,C^{2′}complexes are typically green emissive while 1-phenyl-isoquinolinolato-N,C^{2′}complexes are typically red emissive. In the case of complexes having more than one C,N-cyclometallating ligand, the emission will be that of the ligand having the property of longest wavelength emission. Emission wavelengths may be further shifted by the effects of substituent groups on the C,N-cyclometallating ligands. For example, substitution of electron donating groups at appropriate positions on the N-containing ring A or electron accepting groups on the C-containing ring B tend to blue-shift the emission relative to the unsubstituted C,N-cyclometallated ligand complex. Selecting a monodentate anionic ligand X,Y in formula (J) having more electron accepting properties also tends to blue-shift the emission of a C,N-cyclometallated ligand complex. Examples of complexes having both monoanionic bidentate ligands possessing electron accepting properties and electron accepting substituent groups on the C-containing ring B include bis(2-(4′,6′-difluorophenyl)-pyridinato-N,C^{2′})iridium(III)(picolinate)and bis(2-(4′,6′-difluorophenyl)-pyridinato-N,C^{2′})iridium(II)(tetrakis(1-pyrazolyl)borate). The central metal atom in phosphorescent materials according to formula (J) may be Rh or Ir (m+n=3) and Pd or Pt (m+n=2). Preferred metal atoms are Ir and Pt since they tend to give higher phosphorescent quantum efficiencies according to the stronger spin-orbit coupling interactions generally obtained with elements in the third transition series.

In addition to bidentate C,N-cyclometallating complexes represented by formula (J), many suitable phosphorescent materials contain multidentate C,N-cyclometallating ligands. Phosphorescent materials having tridentate ligands suitable for use in the present invention are disclosed in U.S. Pat. No. 6,824,895 B1 and references therein, incorporated in their entirety herein by reference. Phosphorescent materials having tetradentate ligands suitable for use in the present invention are described by the following formulae:

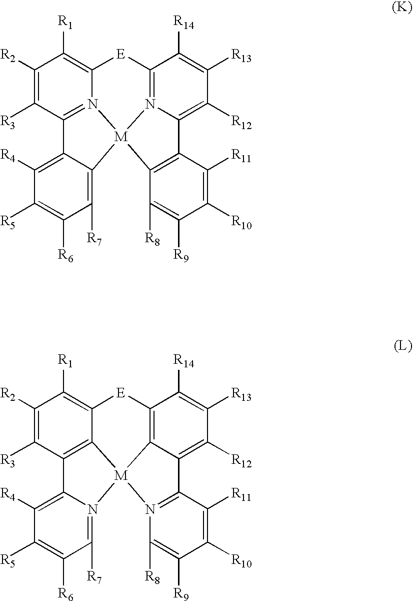

wherein:

M is Pt or Pd;

R¹-R⁷ represent hydrogen or independently selected substituents, provided that R¹ and R², R² and R³, R³ and R⁴, R⁴ and R⁵, R⁵ and R⁶, as well as R⁶ and R⁷ may join to form a ring group;

R⁸-R¹⁴ represent hydrogen or independently selected substituents, provided that R⁸ and R⁹, R⁹ and R¹⁰, R¹⁰ and R¹¹, R¹¹ and R¹², R¹² and R¹³ , as well as R¹³ and R¹⁴, may join to form a ring group;

E represents a bridging group selected from the following:

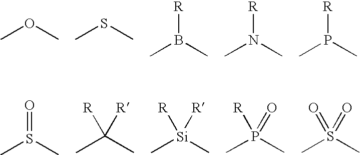

wherein:

R and R′ represent hydrogen or independently selected substituents; provided R and R′ may combine to form a ring group.

One desirable tetradentate C,N-cyclometallated phosphorescent material suitable for use in as the phosphorescent dopant is represented by the following formula:

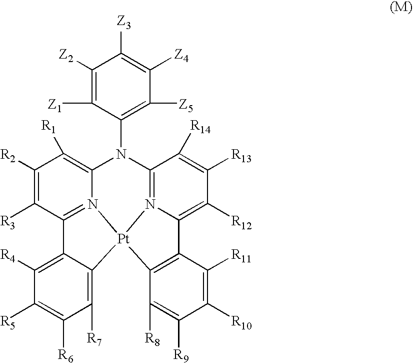

wherein:

R¹-R⁷ represent hydrogen or independently selected substituents, provided that R¹ and R², R² and R³, R³ and R⁴, R⁴ and R⁵, R⁵ and R⁶, as well as R⁶ and R⁷ may combine to form a ring group;

R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may combine to form a ring group;

Z¹-Z⁵ represent hydrogen or independently selected substituents, provided that Z¹ and Z², Z² and Z³, Z³ and Z⁴, as well as Z⁴ and Z⁵ may combine to form a ring group.

Specific examples of phosphorescent materials having tetradentate C,N-cyclometallating ligands suitable for use in the present invention include compounds (M-1), (M-2) and (M-3) represented below.

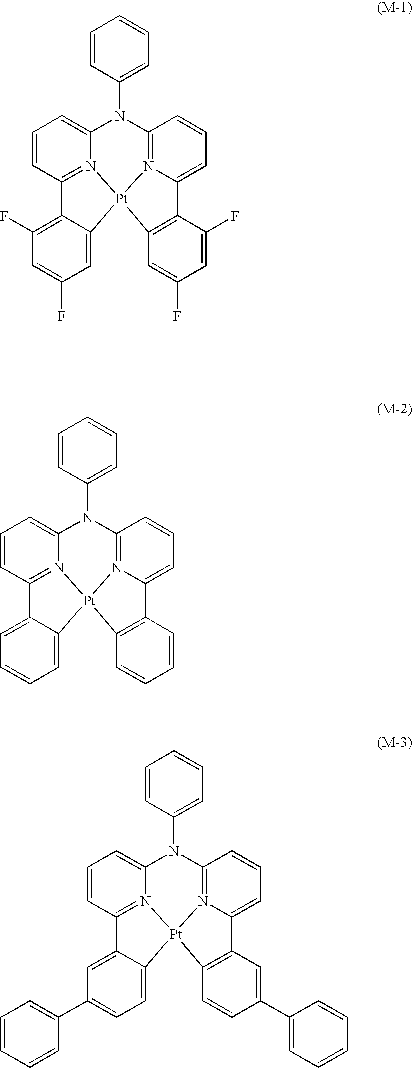

Phosphorescent materials having tetradentate C,N-cyclometallating ligands may be synthesized by reacting the tetradentate C,N-cyclometallating ligand with a salt of the desired metal, such as K₂PtCl₄, in a proper organic solvent such as glacial acetic acid to form the phosphorescent material having tetradentate C,N-cyclometallating ligands. A tetraalkylammonium salt such as tetrabutylammonium chloride can be used as a phase transfer catalyst to accelerate the reaction.

Other phosphorescent materials that do not involve C,N-cyclometallating ligands are known. Phosphorescent complexes of Pt(II), Ir(I), and Rh(I) with maleonitriledithiolate have been reported (Johnson et al., J. Am Chem. Soc., 105,1795 (1983)). Re(I) tricarbonyl diimine complexes are also known to be highly phosphorescent (Wrighton and Morse, J. Am. Chem. Soc., 96, 998 (1974); Stufkens, Comments Inorg. Chem., 13, 359 (1992); Yam, Chem. Commun., 789 (2001)). Os(II) complexes containing a combination of ligands including cyano ligands and bipyridyl or phenanthroline ligands have also been demonstrated in a polymer OLED (Ma et al., Synthetic Metals, 94, 245 (1998)). Porphyrin complexes such as 2,3,7,8,12,13,17,18-octaethyl-21H, 23H-porphine platinum(II) are also useful phosphorescent dopant.

Still other examples of useful phosphorescent materials include coordination complexes of the trivalent lanthanides such as Tb³⁺ and Eu³⁺ (Kido et al., Chem. Lett., 657 (1990); J. Alloys and Compounds, 192, 30 (1993); Jpn. J. Appl. Phys., 35, L394 (1996) and Appl. Phys. Lett., 65, 2124 (1994)).

The phosphorescent dopant in a phosphorescent LEL is typically present in an amount of from 1 to 20% by volume of the LEL, and conveniently from 2 to 8% by volume of the LEL. In some embodiments, the phosphorescent dopant(s) may be attached to one or more host materials. The host materials may further be polymers. The phosphorescent dopant in the first phosphorescent light-emitting layer is selected from green and red phosphorescent materials.

The thickness of a phosphorescent LEL is greater than 0.5 nm, preferably, in the range of from 1.0 nm to 40 nm.

### b) Fluorescent Light Emitting Layers

Although the term “fluorescent” is commonly used to describe any light-emitting material, in this case it refers to a material that emits light from a singlet excited state. Fluorescent materials may be used in the same layer as the phosphorescent material, in adjacent layers, in adjacent pixels, or any combination. Care must be taken not to select materials that will adversely affect the performance of the phosphorescent materials of this invention. One skilled in the art will understand that concentrations and triplet energies of materials in the same layer as the phosphorescent material or in an adjacent layer must be appropriately set so as to prevent unwanted quenching of the phosphorescence.

Typically, a fluorescent LEL includes at least one host and at least one fluorescent dopant. The host may be a hole-transporting material or any of the suitable hosts for phosphorescent dopants as defined above or may be an electron-transporting material as defined below.

The dopant is typically chosen from highly fluorescent dyes, e.g., transition metal complexes as described in WO 98/55561 A1, WO 00/18851 A1, WO 00/57676 A1, and WO 00/70655. Useful fluorescent dopants include, but are not limited to, derivatives of anthracene, tetracene, xanthene, perylene, phenylene, dicyanomethylenepyran compounds, thiopyran compounds, polymethine compounds, pyrylium and thiapyrylium compounds, arylpyrene compounds, arylenevinylene compounds, periflanthene derivatives, indenoperylene derivatives, bis(azinyl)amine boron compounds, bis(azinyl)methane boron compounds, distryrylbenzene derivatives, distyrylbiphenyl derivatives, distyrylamine derivatives and carbostyryl compounds.

Some fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane compounds (as described in U.S. Pat. No. 5,121,029) and carbostyryl compounds. Illustrative examples of useful materials include, but are not limited to, the following:

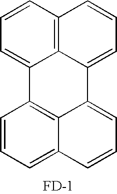

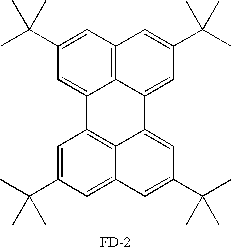

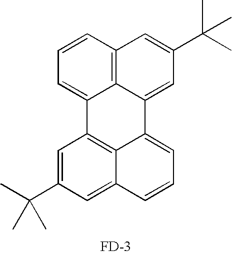

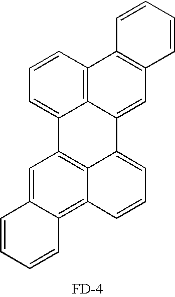

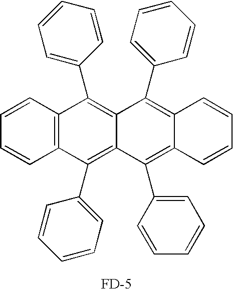

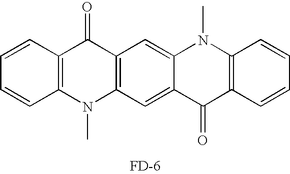

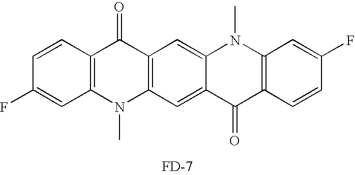

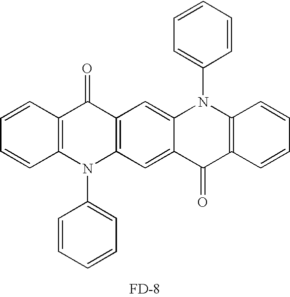

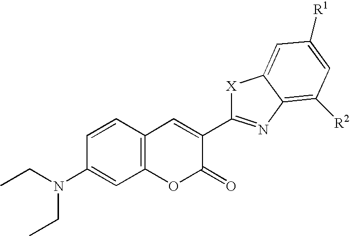

| | X | R1 | R2 |
|---|---|---|---|
| FD-9 | O | H | H |
| FD-10 | O | H | Methyl |
| FD-11 | O | Methyl | H |
| FD-12 | O | Methyl | Methyl |
| FD-13 | O | H | t-butyl |
| FD-14 | O | t-butyl | H |
| FD-15 | O | t-butyl | t-butyl |
| FD-16 | S | H | H |
| FD-17 | S | H | Methyl |
| FD-18 | S | Methyl | H |
| FD-19 | S | Methyl | Methyl |
| FD-20 | S | H | t-butyl |
| FD-21 | S | t-butyl | H |
| FD-22 | S | t-butyl | t-butyl |

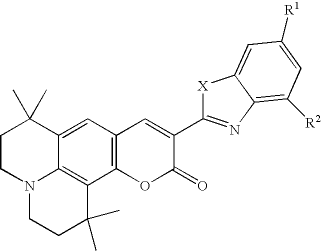

| | X | R1 | R2 |
|---|---|---|---|
| FD-13 | O | H | H |
| FD-24 | O | H | Methyl |
| FD-25 | O | Methyl | H |
| FD-26 | O | Methyl | Methyl |
| FD-27 | O | H | t-butyl |
| FD-28 | O | t-butyl | H |
| FD-29 | O | t-butyl | t-butyl |
| FD-30 | S | H | H |
| FD-31 | S | H | Methyl |
| FD-32 | S | Methyl | H |
| FD-33 | S | Methyl | Methyl |
| FD-34 | S | H | t-butyl |
| FD-35 | S | t-butyl | H |
| FD-36 | S | t-butyl | t-butyl |

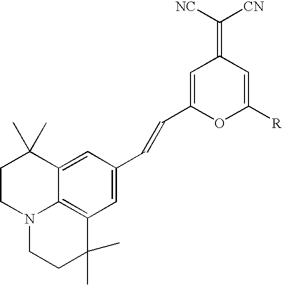

| | R |
|---|---|
| FD-37 | phenyl |
| FD-38 | methyl |
| FD-39 | t-butyl |
| FD-40 | mesityl |

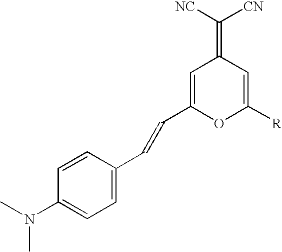

| | R |
|---|---|
| FD-41 | phenyl |
| FD-42 | methyl |
| FD-43 | t-butyl |
| FD-44 | mesityl |

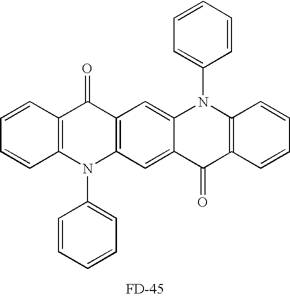

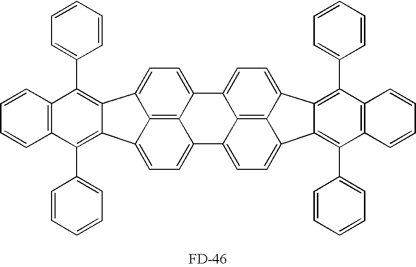

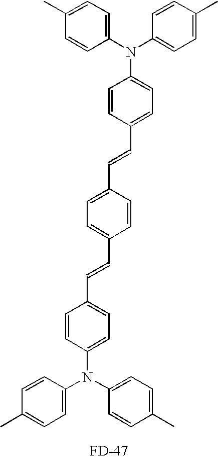

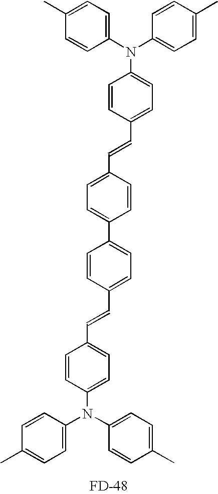

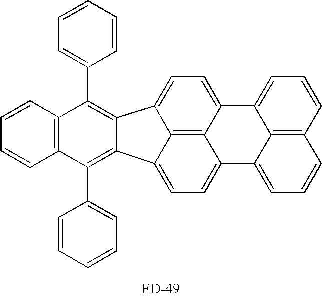

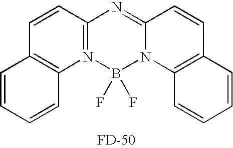

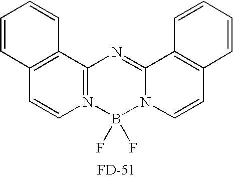

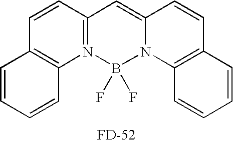

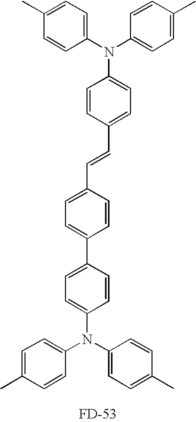

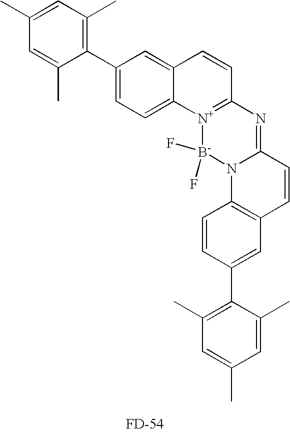

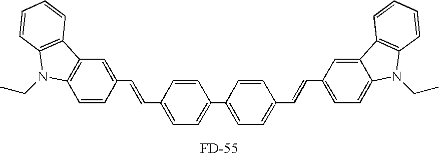

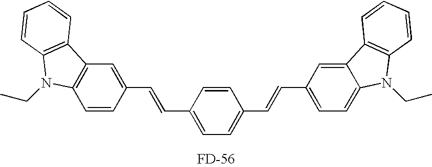

Preferred fluorescent blue dopants may be found in Chen, Shi, and Tang, “Recent Developments in Molecular Organic Electroluminescent Materials,” Macromol. Symp. 125, 1 (1997) and the references cited therein; Hung and Chen, “Recent Progress of Molecular Organic Electroluminescent Materials and Devices,” Mat. Sci. and Eng. R39, 143 (2002) and the references cited therein.

A particularly preferred class of blue-emitting fluorescent dopants is represented by Formula (N), known as a bis(azinyl0amine borane complex, and is described in U.S. Pat. No. 6,661,023.

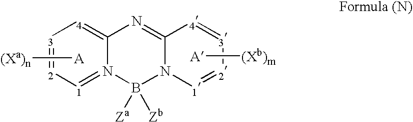

wherein:

A and A′ represent independent azine ring systems corresponding to 6-membered aromatic ring systems containing at least one nitrogen;

each X^{a} and X^{b} is an independently selected substituent, two of which may join to form a fused ring to A or A′;

m and n are independently 0 to 4;

Z^{a} and Z^{b} are independently selected substituents; and

1, 2, 3, 4, 1′, 2′, 3′, and 4′ are independently selected as either carbon or nitrogen atoms.

Desirably, the azine rings are either quinolinyl or isoquinolinyl rings such that 1, 2, 3, 4, 1′, 2′, 3′, and 4′ are all carbon; m and n are equal to or greater than 2; and X^{a} and X^{b} represent at least two carbon substituents which join to form an aromatic ring. Desirably, Z^{a} and Z^{b} are fluorine atoms.

Preferred embodiments further include devices where the two fused ring systems are quinoline or isoquinoline systems; the aryl or heterocyclic substituent is a phenyl group; there are present at least two X^{a} groups and two X^{b} groups which join to form a 6-6 fused ring, the fused ring systems are fused at the 1-2, 3-4, 1′-2′, or 3′-4′positions, respectively; one or both of the fused rings is substituted by a phenyl group; and where the dopant is depicted in Formulae (N-a), (N-b), or (N-c).

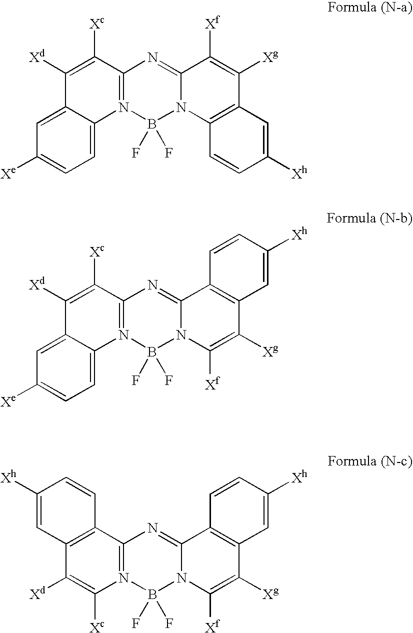

wherein:

each X^{c}, X^{d}, X^{e}, X^{f}, X^{g}, and X^{h} is hydrogen or an independently selected substituent, one of which must be an aryl or heterocyclic group.

Desirably, the azine rings are either quinolinyl or isoquinolinyl rings such that 1, 2, 3, 4, 1′, 2′, 3′, and 4′are all carbon; m and n are equal to or greater than 2; and X^{a} and X^{b} represent at least two carbon substituents which join to form an aromatic ring, and one is an aryl or substituted aryl group. Desirably, Z^{a} and Z^{b} are fluorine atoms.

Of these, compound FD-54 is particularly useful.

Coumarins represent a useful class of green-emitting dopants as described by Tang et al. in U.S. Pat. Nos. 4,769,292 and 6,020,078. Green dopants or light-emitting materials can be coated as 0.01 to 50% by weight into the host material, but typically coated as 0.01 to 30% and more typically coated as 0.01 to 15% by weight into the host material. Examples of useful green-emitting coumarins include C545T and C545TB. Quinacridones represent another useful class of green-emitting dopants. Useful quinacridones are described in U.S. Pat. No. 5,593,788, publication JP 09-13026A, and commonly assigned U.S. patent application Ser. No. 10/184,356 filed Jun. 27, 2002 by Lelia Cosimbescu, entitled “Device Containing Green Organic Light-Emitting Diode”, the disclosure of which is incorporated herein.

Examples of particularly useful green-emitting quinacridones are FD-7 and FD-8.

Formula (N-d) below represents another class of green-emitting dopants useful in the invention.

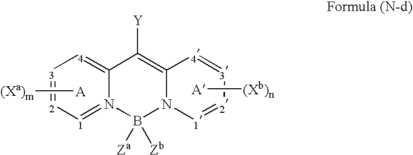

wherein:

A and A′ represent independent azine ring systems corresponding to 6-membered aromatic ring systems containing at least one nitrogen;

each X^{a} and X^{b} is an independently selected substituent, two of which may join to form a fused ring to A or A′;

m and n are independently 0 to 4;

Y is H or a substituent;

Z^{a} and Z^{b} are independently selected substituents; and

1, 2, 3, 4, 1′, 2′, 3′, and 4′are independently selected as either carbon or nitrogen atoms.

In the device, 1, 2, 3, 4, 1′, 2′, 3′, and 4′are conveniently all carbon atoms. The device may desirably contain at least one or both of ring A or A′ that contains substituents joined to form a fused ring. In one useful embodiment, there is present at least one X^{a} or X^{b} group selected from the group consisting of halide and alkyl, aryl, alkoxy, and aryloxy groups. In another embodiment, there is present a Z^{a} and Z^{b} group independently selected from the group consisting of fluorine and alkyl, aryl, alkoxy and aryloxy groups. A desirable embodiment is where Z^{a} and Z^{b} are F. Y is suitably hydrogen or a substituent such as an alkyl, aryl, or heterocyclic group.

The emission wavelength of these compounds may be adjusted to some extent by appropriate substitution around the central bis(azinyl)methene boron group to meet a color aim, namely green. Some examples of useful material are FD-50, FD-51 and FD-52.

Naphthacenes and derivatives thereof also represent a useful class of emitting dopants, which can also be used as stabilizers. These dopant materials can be coated as 0.01 to 50% by weight into the host material, but typically coated as 0.01 to 30% and more typically coated as 0.01 to 15% by weight into the host material. Naphthacene derivative YD-1 (t-BuDPN) below, is an example of a dopant material used as a stabilizer.

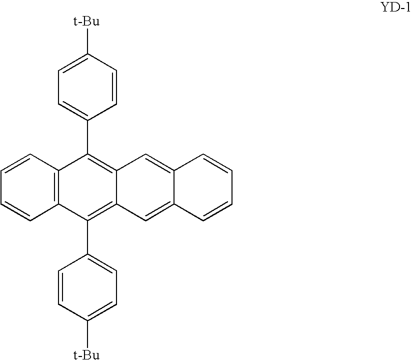

Some examples of this class of materials are also suitable as host materials as well as dopants. For example, see U.S. Pat. No. 6,773,832 or U.S. Pat. No. 6,720,092. A specific example of this would be rubrene (FD-5).

Another class of useful dopants are perylene derivatives; for example see U.S. Pat. No. 6,689,493. A specific example is FD-46.

Metal complexes of 8-hydroxyquinoline and similar derivatives (Formula O) constitute one class of useful non-electroluminescent host compounds capable of supporting electroluminescence, and are particularly suitable for light emission of wavelengths longer than 500 nm, e.g., green, yellow, orange, and red.

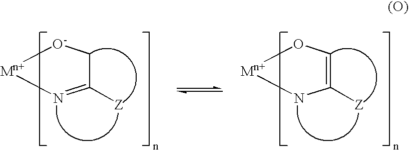

wherein:

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such as aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
O-1: Aluminum trisoxine [alias, tris(8-quinolinolato)aluminum(III)]
O-2: Magnesium bisoxine [alias, bis(8-quinolinolato)magnesium(II)]
O-3: Bis[benzo{f}-8-quinolinolato]zinc (II)
O-4: Bis(2-methyl-8-quinolinolato)aluminum(III)-μ-oxo-bis(2-methyl-8-quinolinolato) aluminum(III)
O-5: Indium trisoxine [alias, tris(8-quinolinolato)indium]
O-6: Aluminum tris(5-methyloxine) [alias, tris(5-methyl-8-quinolinolato) aluminum(III)]
O-7: Lithium oxine [alias, (8-quinolinolato)lithium(I)]
O-8: Gallium oxine [alias, tris(8-quinolinolato)gallium(III)]
O-9: Zirconium oxine [alias, tetra(8-quinolinolato)zirconium(IV)]
O-10: Bis(2-methyl-8-quinolinato)-4-phenylphenolatoaluminum (III)

Anthracene derivatives according to formula (P) are also useful host materials in the LEL:

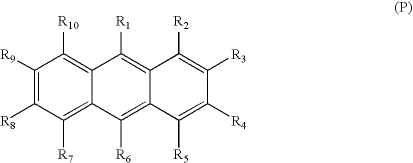

wherein:

R₁-R₁₀ are independently chosen from hydrogen, alkyl groups from 1-24 carbon atoms or aromatic groups from 1-24 carbon atoms. Particularly preferred are compounds where R₁ and R₆ are phenyl, biphenyl or napthyl, R₃ is phenyl, substituted phenyl or napthyl and R₂, R₄, R₅, R₇-R₁₀ are all hydrogen. Such anthracene hosts are known to have excellent electron transporting properties.

Particularly desirable are derivatives of 9,10-di-(2-naphthyl)anthracene. Illustrative examples include 9,10-di-(2-naphthyl)anthracene (ADN) and 2-t-butyl-9, 10-di-(2-naphthyl)anthracene (TBADN). Other anthracene derivatives can be useful as an non-electroluminescent compound in the LEL, such as diphenylanthracene and its derivatives, as described in U.S. Pat. No. 5,927,247. Styrylarylene derivatives as described in U.S. Pat. No. 5,121,029 and JP 08333569 are also useful non-electroluminescent materials. For example, 9,10-bis[4-(2,2-diphenylethenyl)phenyl]anthracene, 4,4′-Bis(2,2-diphenylethenyl)-1,1′-biphenyl (DPVBi) and phenylanthracene derivatives as described in EP 681,019 are useful non-electroluminescent materials.

Some illustrative examples of suitable anthracenes are:

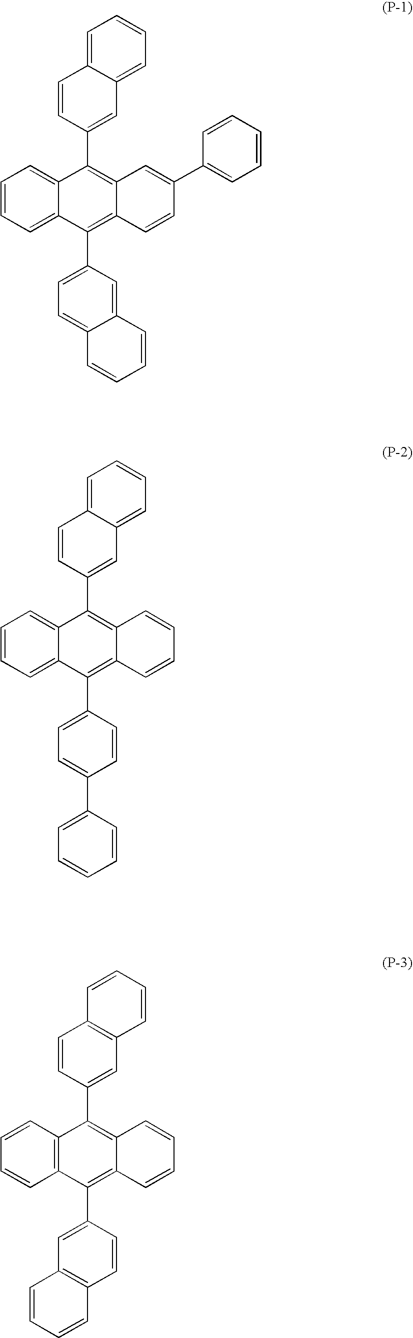

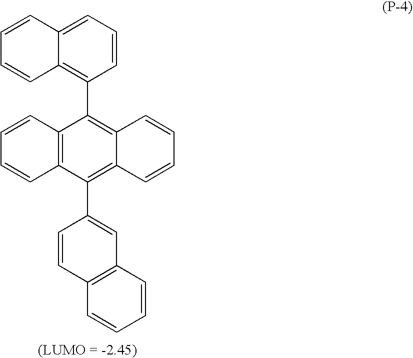

Spacer layers, when present, are located in direct contact to a LEL. They may be located on either the anode or cathode, or even both sides of the LEL. They typically do not contain any light-emissive dopants. One or more materials may be used and could be either a hole-transporting material as defined above or an electron-transporting material as defined below. If located next to a phosphorescent LEL, the material in the spacer layer should have higher triplet energy than that of the phosphorescent dopant in the LEL. Most desirably, the material in the spacer layer will be the same as used as the host in the adjacent LEL. Thus, any of the host materials described as also suitable for use in a spacer layer. The spacer layer should be thin; at least 0.1 nm, but preferably in the range of from 1.0 nm to 20 nm.

When a LEL containing a phosphorescent emitter is present, it is desirable to locate a hole-blocking layer between the electron-transporting layer and the light-emitting layer to help confine the excitons and recombination events to the LEL. In this case, there should be an energy barrier for hole migration from co-hosts into the hole-blocking layer, while electrons should pass readily from the hole-blocking layer into the light-emitting layer comprising co-host materials and a phosphorescent emitter. It is further desirable that the triplet energy of the hole-blocking material be greater than that of the phosphorescent material. Suitable hole-blocking materials are described in WO 00/70655A2, WO 01/41512 and WO 01/93642 A1. Two examples of useful hole-blocking materials are bathocuproine (BCP) and bis(2-methyl-8-quinolinolato)(4-phenylphenolato)aluminum(III) (BAlq). Metal complexes other than BA1q are also known to block holes and excitons as described in US 20030068528.

When a hole-blocking layer is used, its thickness can be between 2 and 100 nm and suitably between 5 and 10 nm.

In addition to any of the electron-transporting materials previously described, any other materials known to be suitable for use in the ETL may be used. Included are, but are not limited to, chelated oxinoid compounds, anthracene derivatives, pyridine-based materials, imidazoles, oxazoles, thiazoles and their derivatives, polybenzobisazoles, cyano-containing polymers and perfluorinated materials. Other electron-transporting materials include various butadiene derivatives as disclosed in U.S. Pat. No. 4,356,429 and various heterocyclic optical brighteners as described in U.S. Pat. No. 4,539,507.

A preferred class of benzazoles is described by Shi et al. in U.S. Pat. Nos. 5,645,948 and 5,766,779. Such compounds are represented by structural formula (Q):

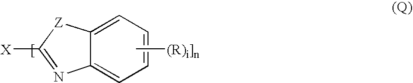

In formula (Q), n is selected from 2 to 8 and i is selected from 1-5;

Z is independently O, NR or S;

R is individually hydrogen; alkyl of from 1 to 24 carbon atoms, for example, propyl, t-butyl, heptyl, and the like; aryl or hetero-atom substituted aryl of from 5 to 20 carbon atoms, for example, phenyl and naphthyl, furyl, thienyl, pyridyl, quinolinyl and other heterocyclic systems; or halo such as chloro, fluoro; or atoms necessary to complete a fused aromatic ring; and

X is a linkage unit consisting of carbon, alkyl, aryl, substituted alkyl, or substituted aryl, which conjugately or unconjugately connects the multiple benzazoles together.

An example of a useful benzazole is 2,2′,2″-(1,3,5-phenylene)tris[1-phenyl-1H-benzimidazole] (TPBI) represented by a formula (Q-1) shown below:

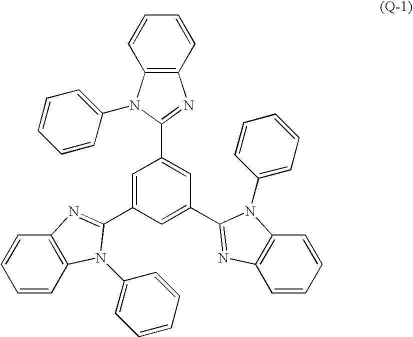

Another suitable class of the electron-transporting materials includes various substituted phenanthrolines as represented by formula (R):

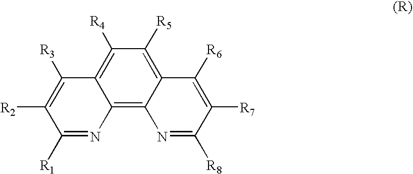

In formula (R), R₁-R₈ are independently hydrogen, alkyl group, aryl or substituted aryl group, and at least one of R₁-R₈ is aryl group or substituted aryl group.

Examples of suitable materials are 2,9-dimethyl-4,7-diphenyl-phenanthroline (BCP) (see formula (R-1)) and 4,7-diphenyl-1,10-phenanthroline (Bphen) (see formula (R-2)).

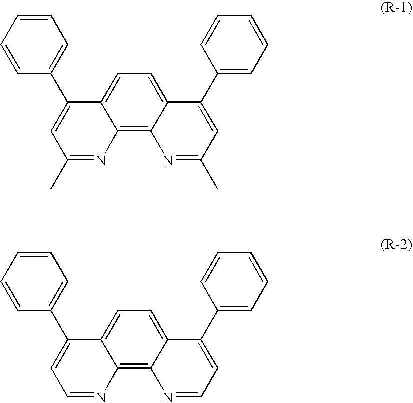

Suitable triarylboranes that function as an electron-transporting material may be selected from compounds having the chemical formula (S):

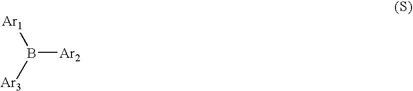

wherein:

Ar₁ to Ar₃ are independently an aromatic hydrocarbocyclic group or an aromatic heterocyclic group which may have a substituent. It is preferable that compounds having the above structure are selected from formula (S-1):

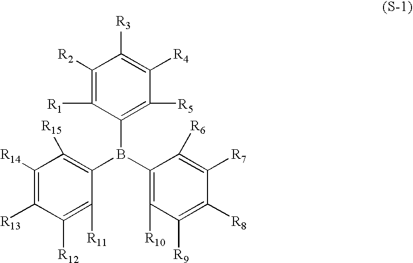

wherein:

R₁-R₁₅ are independently hydrogen, fluoro, cyano, trifluoromethyl, sulfonyl, alkyl, aryl or substituted aryl group.

Specific representative embodiments of the triarylboranes include:

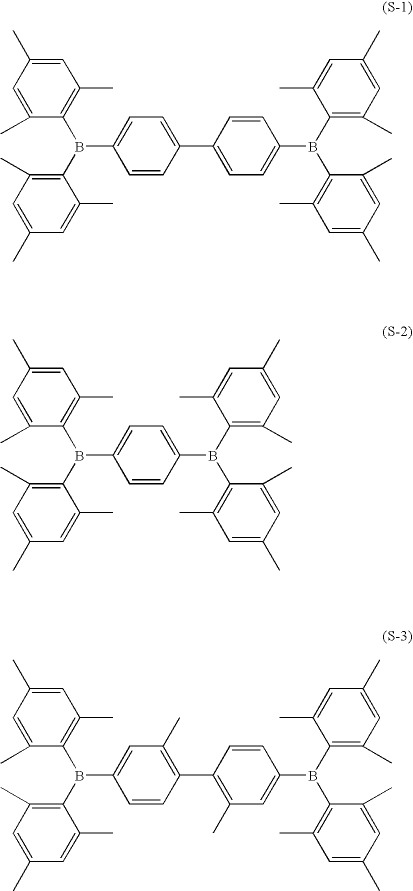

The electron-transporting material may also be selected from substituted 1,3,4-oxadiazoles of formula (T):

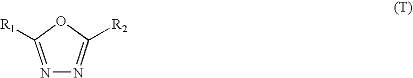

wherein:

R₁ and R₂ are individually hydrogen; alkyl of from 1 to 24 carbon atoms, for example, propyl, t-butyl, heptyl, and the like; aryl or hetero-atom substituted aryl of from 5 to 20 carbon atoms, for example, phenyl and naphthyl, furyl, thienyl, pyridyl, quinolinyl and other heterocyclic systems; or halo such as chloro, fluoro; or atoms necessary to complete a fused aromatic ring.

Illustrative of the useful substituted oxadiazoles are the following:

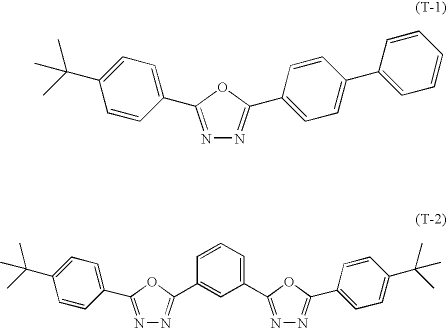

The electron-transporting material may also be selected from substituted 1,2,4-triazoles according to formula (U):

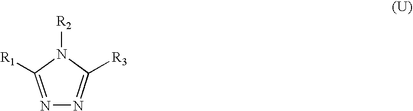

wherein:

R₁, R₂ and R₃ are independently hydrogen, alkyl group, aryl or substituted aryl group, and at least one of R₁-R₃ is aryl group or substituted aryl group. An example of a useful triazole is 3-phenyl-4-(1-naphtyl)-5-phenyl-1,2,4-triazole represented by formula (U-1):

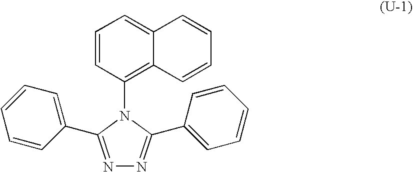

The electron-transporting material may also be selected from substituted 1,3,5-triazines. Examples of suitable materials are:

2,4,6-tris(diphenylamino)-1,3,5-triazine;

2,4,6-tricarbazolo-1,3,5-triazine;

2,4,6-tris(N-phenyl-2-naphthylamino)-1,3,5-triazine;

2,4,6-tris(N-phenyl-1-naphthylamino)-1,3,5-triazine;

4,4′,6,6′-tetraphenyl-2,2′-bi-1,3,5-triazine;

2,4,6-tris([1,1′:3′,1″-terphenyl]-5′-yl)-1,3,5-triazine.

In addition, any of the metal chelated oxinoid compounds including chelates of oxine itself (also commonly referred to as 8-quinolinol or 8-hydroxyquinoline) of Formula (O) useful as host materials in a LEL are also suitable for use in the ETL.

Some metal chelated oxinoid compounds having high triplet energy can be particularly useful as an electron-transporting materials. Particularly useful aluminum or gallium complex host materials with high triplet energy levels are represented by Formula (V).

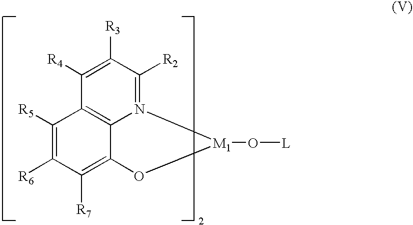

In Formula (V), M₁ represents Al or Ga. R₂-R₇ represent hydrogen or an independently selected substituent. Desirably, R₂ represents an electron-donating group. Suitably, R₃ and R₄ each independently represent hydrogen or an electron donating substituent. A preferred electron-donating group is alkyl such as methyl. Preferably, R₅, R₆, and R₇ each independently represent hydrogen or an electron-accepting group. Adjacent substituents, R₂-R₇, may combine to form a ring group. L is an aromatic moiety linked to the aluminum by oxygen, which may be substituted with substituent groups such that L has from 6 to 30 carbon atoms.

Illustrative of useful chelated oxinoid compounds for use in the ETL is Aluminum(III) bis(2-methyl-8-hydroxyquinoline)-4-phenylphenolate [alias, Balq].

The same anthracene derivatives according to formula (P) useful as host materials in the LEL can also be used in the ETL.

The thickness of the ETL is in the range of from 5 nm to 200 nm, preferably, in the range of from 10 nm to 150 nm.

An EIL is typically located adjacent and in contact with the anode. It serves to promote electron transport from the anode into the other organic layers. For example, the EIL may be an n-type doped layer containing at least one electron-transporting material as a host and at least one n-type dopant. The dopant is capable of reducing the host by charge transfer. The term “n-type doped layer” means that this layer has semiconducting properties after doping, and the electrical current through this layer is substantially carried by the electrons.

The host in the EIL may be an electron-transporting material capable of supporting electron injection and electron transport. The electron-transporting material can be selected from the electron-transporting materials for use in the ETL region as defined above and as discussed for the n-type organic connector layer. The n-type dopant in the n-type doped EIL can be selected from the same materials as discussed for use in electron-transporting materials for use in the ETL region as defined above and as discussed for the n-type organic connector layer for the n-type organic connector layer.

The thickness of the EIL is typically less than 20 nm, and preferably in the range of less than 5 nm. When an n-type doped EIL is employed, the thickness is typically less than 200 nm, and preferably in the range of less than 150 nm.

When light emission is viewed solely through the anode, the cathode 170 includes nearly any conductive material. Desirable materials have effective film-forming properties to ensure effective contact with the underlying organic layer, promote electron injection at low voltage, and have effective stability. Useful cathode materials often contain a low work function metal (<4.0 eV) or metal alloy. One preferred cathode material includes a Mg:Ag alloy as described in U.S. Pat. No. 4,885,221. Another suitable class of cathode materials includes bilayers including a thin inorganic EIL in contact with an organic layer (e.g., organic EIL or ETL), which is capped with a thicker layer of a conductive metal. Here, the inorganic EIL preferably includes a low work function metal or metal salt and, if so, the thicker capping layer does not need to have a low work function. One such cathode includes a thin layer of LiF followed by a thicker layer of A1 as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, cathode 170 should be transparent or nearly transparent. For such applications, metals should be thin or one should use transparent conductive oxides, or include these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials are typically deposited by thermal evaporation, electron beam evaporation, ion sputtering, or chemical vapor deposition. When needed, patterning is achieved through many well known methods including, but not limited to, through-mask deposition, integral shadow masking, for example as described in U.S. Pat. No. 5,276,380 and EP 0 732 868, laser ablation, and selective chemical vapor deposition.

Tandem OLED 100 is typically provided over a supporting substrate where either the anode 110 or cathode 170 can be in contact with the substrate. The electrode in contact with the substrate is conveniently referred to as the bottom electrode. Conventionally, the bottom electrode is the anode 120, but this invention is not limited to that configuration. Note that the substrate may alternatively be located adjacent to the cathode, or the substrate may actually constitute the anode or cathode.

The substrate can either be light transmissive or opaque, depending on the intended direction of light emission. The light transmissive property is desirable for viewing the EL emission through the substrate. Transparent glass or plastic is commonly employed in such cases. The substrate can be a complex structure comprising multiple layers of materials. This is typically the case for active matrix substrates wherein TFTs are provided below the OLED layers. It is still necessary that the substrate, at least in the emissive pixelated areas, be comprised of largely transparent materials such as glass or polymers. For applications where the EL emission is viewed through the top electrode, the transmissive characteristic of the bottom support is immaterial, and therefore the substrate can be light transmissive, light absorbing or light reflective. Substrates for use in this case include, but are not limited to, glass, plastic, semiconductor materials such as silicon, ceramics, and circuit board materials. Again, the substrate can be a complex structure comprising multiple layers of materials such as found in active matrix TFT designs. It is necessary to provide in these device configurations a light-transparent top electrode.

The organic materials mentioned above are suitably deposited through sublimation, but can be deposited from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,851,709 and U.S. Pat. No. 6,066,357) and inkjet method (U.S. Pat. No. 6,066,357).

Organic materials useful in making OLEDs, for example organic hole-transporting materials, organic light-emitting materials doped with an organic electroluminescent components have relatively complex molecular structures with relatively weak molecular bonding forces, so that care must be taken to avoid decomposition of the organic material(s) during physical vapor deposition. The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the organic material, the vapor condensing on a substrate to provide an organic layer thereon.

Several problems have been observed in using organic powders, flakes, or granules in physical vapor deposition: These powders, flakes, or granules are difficult to handle. These organic materials generally have a relatively low physical density and undesirably low thermal conductivity, particularly when placed in a physical vapor deposition source which is disposed in a chamber evacuated to a reduced pressure as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; This can lead to nonuniform heating of such organic materials in physical vapor deposition sources. Therefore, result in potentially nonuniform vapor-deposited organic layers formed on a substrate.

These organic powders can be consolidated into a solid pellet. These solid pellets consolidating into a solid pellet from a mixture of a sublimable organic material powder are easier to handle. Consolidation of organic powder into a solid pellet can be accomplished with relatively simple tools. A solid pellet formed from mixture comprising one or more non-luminescent organic non-electroluminescent component materials or luminescent electroluminescent component materials or mixture of non-electroluminescent component and electroluminescent component materials can be placed into a physical vapor deposition source for making organic layer. Such consolidated pellets can be used in a physical vapor deposition apparatus.

In one aspect, the present invention provides a method of making an organic layer from compacted pellets of organic materials on a substrate, which will form part of an OLED.

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; U.S. Ser. No. 10/945,940; U.S. Ser. No. 10/945,941; U.S. Ser. No. 11/050,924; and U.S. Pat. No. 11/050,934. Using this second method, each material may be evaporated using different source evaporators or the solid materials may be mixed prior to evaporation using the same source evaporator.

### Encapsulation

Most OLED devices are sensitive to moisture and/or oxygen so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890.

For full color display, the pixelation of LELs can be needed. This pixelated deposition of LELs is achieved using shadow masks, integral shadow masks, U.S. Pat. No. 5,294,870, spatially defined thermal dye transfer from a donor sheet, U.S. Pat. Nos. 5,688,551, 5,851,709, and 6,066,357, and inkjet method, U.S. Pat. No. 6,066,357.

OLEDs of this invention can employ various well-known optical effects in order to enhance their emissive properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color-conversion filters over the display. Filters, polarizers, and anti-glare or anti-reflection coatings may be specifically provided over the OLED or as part of the OLED.

Embodiments of the invention may provide EL devices that have good luminance efficiency, good operational stability, and reduced drive voltages. Embodiments of the invention may also give reduced voltage rises over the lifetime of the devices and can be produced with high reproducibility and consistently to provide good light efficiency. They may have lower power consumption requirements and, when used with a battery, provide longer battery lifetimes.

The present invention can be employed in most OLED device applications. These include very simple structures comprising a single anode and cathode to more complex devices, such as area color displays, passive matrix displays comprised of orthogonal arrays of anodes and cathodes to form pixels, and active matrix displays where each pixel is controlled independently, for example, with thin film transistors (TFTs). The invention can also be employed for devices where the OLED is used as a light source, for example, in solid-state lighting or backlights for LCD displays.

As used herein and throughout this application, the term carbocyclic and heterocyclic rings or groups are generally as defined by the Grant & Hackh's Chemical Dictionary, Fifth Edition, McGraw-Hill Book Company. For the purpose of this invention, also included in the definition of a heterocyclic ring are those rings that include coordinate bonds. The definition of a coordinate or dative bond can be found in Grant & Hackh's Chemical Dictionary, pages 91 and 153. The definition of a ligand, including a bidentate ligand, can be found in Grant & Hackh's Chemical Dictionary, pages 337 and 176, respectively.

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl g N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

### EXAMPLES

The following examples are presented for a further understanding of the present invention. The EL characteristics of all the fabricated devices were evaluated using a constant current source (KEITHLEY 2400 SourceMeter) and a photometer (PHOTO RESEARCH SpectraScan PR 650) at room temperature. The color is reported using Commission Internationale de l'Eclairage (CIE) coordinates. For layers containing mixtures of materials, the relative amounts given are in % by volume. T50 is the time required for the luminance to decrease by 50% of the initial amount when the device is held at 80 mA/cm². cd/A is candela per amp and is a measure of the efficiency to produce light.

### Example 1-1

A comparative tandem OLED was prepared in the following manner:
1. A clean glass substrate was deposited by sputtering with indium tin oxide (ITO) to form a transparent anode of 60 nm thickness.
2. The above-prepared ITO surface was treated with a plasma oxygen etch.
3. The above-prepared substrate was further treated by vacuum-depositing a 10 nm layer of hexacyanohexaazatriphenylene (CHATP) as a hole-injecting layer (HTL).

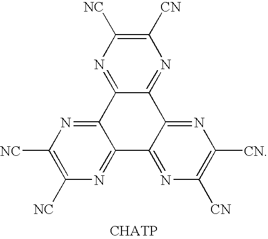

4. The above-prepared substrate was further treated by vacuum-depositing a 120 nm layer of 4,4′-bis[N-(1-naphthyl)-N-phenylamino]biphenyl (NPB) as a hole-transporting layer (HTL).
5. The above-prepared substrate was further treated by vacuum-depositing a 30 nm yellow light-emitting layer (LEL) including 23% NPB (as co-host) and 75% 9-(2-naphthyl)-10-(1-napthyl)anthracene (P-4) as a host with 2% yellow-orange emitting dopant diphenyltetra-t-butylrubrene (PTBR).

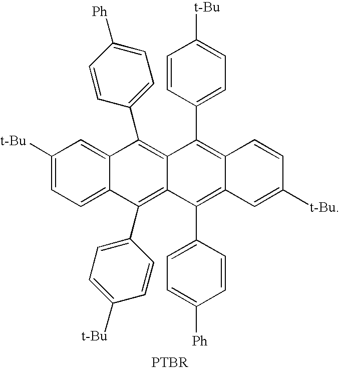

6. A 10 nm spacer layer consisting of 25% NPB and 75% BNA was then deposited.
7. The above-prepared substrate was further treated by vacuum-depositing a 30 nm blue light-emitting layer including 97% P-4 as a host and 3% FD-53 as blue-emitting dopant.
8. A 40 nm n-type doped organic layer was vacuum-deposited, including 49% 4,7-diphenyl-1,10-phenanthroline (Bphen), 49% tris(8-quinolinolato)aluminum (III) (ALQ) as co-host, with 2% Li metal.
9. The above-prepared substrate was further treated by vacuum-depositing a 10 nm layer of CHATP as an electron accepting organic layer.
10. The above-prepared substrate was further treated by vacuum-depositing a 10 nm layer of NPB as a hole-transporting layer (HTL).
11. The above-prepared substrate was further treated by vacuum-depositing a 16 nm red light-emitting layer including 24.5% of NPB as co-host, 75% of P-4 as a host and 0.5% dibenzo {[ff′]-4,4′7,7′-tetraphenyl]diindeno-[1,2,3-cd: 1′,2′,3′-lm]perylene (TPDBP) as a red emitting dopant.
12. The above-prepared substrate was further treated by vacuum-depositing a 4 nm yellow light emitting layer including 75% of P-4 host, 23% NPB as co-host and 2% PTBR as a yellow emitting dopant.
13. The above-prepared substrate was further treated by vacuum-depositing a 40 nm green light-emitting layer including 94% 2-phenyl-9,10-bis(2-naphthyl)anthracene (P-1) host, 5% green dopant DPADPA, and 1% BEP blue dopant.

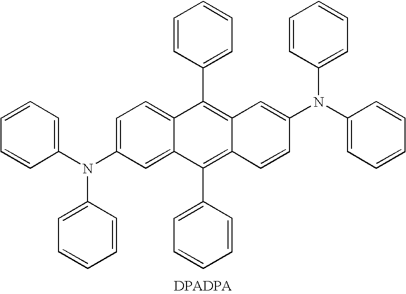

14. A 40 nm electron injection layer was vacuum-deposited, including 49 Bphen, 49% ALQ as co-host, with 2% Li metal.
15. A 100 nm layer of aluminum was evaporatively deposited onto the substrate to form a cathode layer.

The above sequence completes the deposition of the EL device. The device was then hermetically packaged in a dry glove box for protection against ambient environment.

It should be noted that in Example 1, the layers corresponding to steps 3-7 represent a second light emitting unit that produces predominately blue light, the layers corresponding to steps 8 and 9 represent the connector composed of a n-type doped organic layer and an electron accepting layer and the layers corresponding to steps 10-14 represent a first light emitting unit that produces predominately green and longer wavelength light.

Inventive Example 1-2 was prepared in the same manner as Example 1-1 but the ALQ in the n-doped organic layer (step 8) was replaced with 49% CaC-7. Inventive Example 1-3 is like Example 1-2 except GaC-9 replaces GaC-7. Performance data is shown in Table 1.

TABLE 1
Efficiency, Color and Stability of Tandem OLEDs

| Example | Voltage | cd/A | CIEx | CIEy | T50 (hours) |
|---|---|---|---|---|---|
| 1-1 (Comp) | 9.8 | 22.5 | 0.354 | 0.369 | 900 |
| 1-2 (Inv) | 10.4 | 23.1 | 0.356 | 0.355 | 1100 |
| 1-3 (Inv) | 10.3 | 23.2 | 0.358 | 0.362 | 1000 |

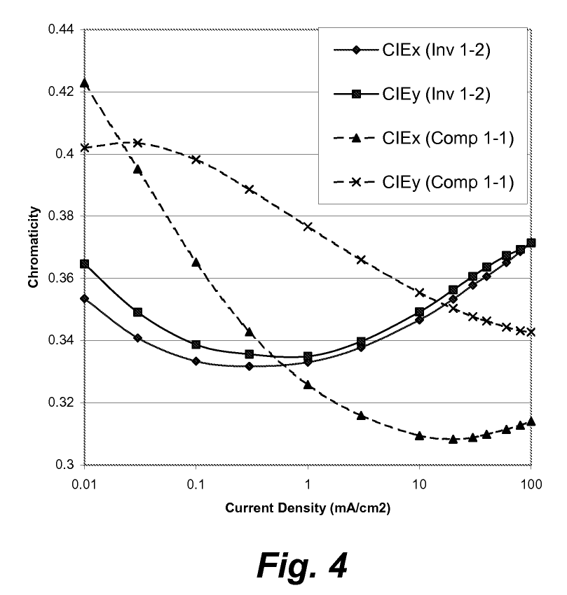

It can be seen from the data in Table 1 that the inventive examples have increased efficiency and stability at equivalent color although the voltage is slightly higher. As shown in FIG. 4 and Table 2, the tandem devices prepared according to this invention demonstrate improved relative luminance change as a function of applied current. This test measures the color output as a function of current density over 0.01 to 100 mA/cm². Devices with an organic gallium complex in the n-type doped layer are far superior to the check in terms of minimizing color change over a wide range of applied current.

TABLE 2
Color Change vs Current Density of Tandem OLEDs

| Example | Delta CIEx | Delta CIEy | Delta CIE |
|---|---|---|---|
| 1-1 (Comp) | 0.095 | 0.074 | 0.121 |
| 1-2 (Inv) | 0.039 | 0.036 | 0.053 |
| 1-3 (Inv) | 0.039 | 0.038 | 0.055 |

Inventive Examples 1-4 to 1-10 were prepared analogous to Example 1-1 except that the n-type doped organic layer was divided into two sublayers. The first sublayer was a 4 nm layer added between the blue LEL of step 7 and the second sublayer, whose thickness was changed to 36 nm, and which was applied before the electron accepting layer of step 9. The components of these sublayers are listed in Table 3 and performance results shown in Table 4.

TABLE 3
Materials Used in Inventive Examples 1-4 to 1-10

| Example | 1^{st} Sublayer | 2^{nd} Sublayer |
|---|---|---|
| 1-1 (Comp) | None | 49% Bphen + 49% ALQ + |
| | | 2% Li |
| 1-4 (Inv) | 100% GaC-8 | 98% GaC-8 + 2% Li |
| 1-5 (Inv) | 98% GaC-8 + 2% Li | 49% GaC-8 + 49% |
| | | Bphen + 2% Li |
| 1-6 (Inv) | 79% GaC-8 + 19% GaC- | 49% GaC-7 + 49% |
| | 7 + 2% Li | Bphen + 2% Li |
| 1-7 (Inv) | 98% GaC-8 + 2% Li | 98% GaC-9 + 2% Li |
| 1-8 (Inv) | 98% GaC-8 + 2% Li | 49% GaC-9 + 49% |
| | | Bphen + 2% Li |
| 1-9 (Inv) | 99% GaC-8 + 1% Li | 49% GaC-9 + 49% |
| | | Bphen + 2% Li |
| 1-10 (Inv) | 99% GaC-8 + 1% Li | 49% GaC-7 + 49% |
| | | Bphen + 2% Li |

TABLE 4
Efficiency, Color and Stability of Tandem OLEDs

| Example | Voltage | cd/A | CIEx | CIEy | T50 (hours) |
|---|---|---|---|---|---|
| 1-1 (Comp) | 9.8 | 22.5 | 0.354 | 0.369 | 900 |
| 1-4 (Inv) | 9.9 | 25.3 | 0.372 | 0.370 | 680 |
| 1-5 (Inv) | 8.5 | 26.1 | 0.459 | 0.449 | 950 |
| 1-6 (Inv) | 9.1 | 25.3 | 0.406 | 0.407 | 1000 |
| 1-7 (Inv) | 9.3 | 26.6 | 0.423 | 0.421 | 900 |
| 1-8 (Inv) | 8.6 | 27.2 | 0.436 | 0.442 | 1100 |
| 1-9 (Inv) | 8.4 | 22.9 | 0.364 | 0.407 | 700 |
| 1-10 (Inv) | 8.4 | 23.1 | 0.355 | 0.379 | 750 |

The results in Table 4 demonstrates that even lower voltage and higher efficiencies can be obtained by subdividing the n-type doped organic layer, although other features such as color and stability are compromised. This series of examples also show little change in color as a function of current density.

In addition, the data indicates that lower voltage is obtained when both sublayers contain an n-type dopant (in this case, lithium metal). Also, better performance is obtained whenever materials that have a LUMO energy level less negative than the LUMO energy level of the primary host material in the closest light emitting layer of the second light emitting unit. For example, inventive example 1-8, which exhibits low voltage, contains GaC-8 with a LUMO energy level of −2.32 eV relative to P-4 (the host of the nearest LEL in the second light emitting unit) with a LUMO of −2.45 eV. It is also desirable that the LUMO energy level of the material in the sublayer in contact with the second light emitting unit is the same or less negative than the gallium complex in the other sublayer. For inventive example 1-8, GaC-8 is −2.32 eV relative to GaC-9 with a LUMO of −2.64 eV.

The invention has been described in detail with particular reference to certain preferred embodiments thereof, but it will be understood that variations and modifications can be effected within the spirit and scope of the invention.

### PARTS LIST

100 tandem OLED
110 anode
120.1 first EL unit
120.2 second EL unit
120.(N−1) (N−1)^{th} EL unit
120.N N^{th} EL unit
130.1 first intermediate connector
130.2 second intermediate connector
130.(N−1) (N−1)^{th} intermediate connector
170 cathode
180 voltage/current source
190 electrical conductors
200 tandem OLED device
210 anode
220.1 first EL unit
220.2 second EL unit
221.1 HIL of the 1^{st} EL unit
222.1 HTL of the 1^{st} EL unit
222.2 HTL of the 2^{nd} EL unit
223.1 LEL1 of the 1^{st} EL unit
223.2 LEL2 of the 1^{st} EL unit
223.3 LEL3 of the 1^{st} EL unit
223.4 LEL1 of the 2^{nd} EL unit
223.5 LEL2 of the 2^{nd} EL unit
223.6 LEL3 of the 2_{nd} EL unit
230.1 intermediate connector
231.1 n-type doped organic layer
233.1 electron-accepting layer
226.2 EIL of the 2_{nd} EL unit
270 cathode

### PARTS LIST (con't)

300 tandem OLED device
310 anode
320.1 first EL unit
320.1 second EL unit
321.1 HIL of the 1^{st} EL unit
322.1 HTL of the 1^{st} EL unit
322.2 HTL of the 2^{nd} EL unit
323.1 LEL of the 1^{st} EL unit
323.2 LEL of the 2^{nd} EL unit
324.1 ETL of the 1^{st} EL unit
324.2 ETL of the 2^{nd} nd EL unit
330.1 intermediate connector
331 n-type doped organic layer
332.1 n-type doped organic sublayer 1
332.2 n-type doped organic sublayer 2
333.1 electron-accepting layer
EIL of the 2^{nd} EL unit
370 cathode

1. A tandem OLED device having two spaced electrodes comprising:
a) first and second light-emitting units disposed between the electrodes wherein each light emitting unit has at least one light emitting layer; and
b) an intermediate connector disposed between each of the light-emitting units and having:
i) an electron accepting organic layer in contact with the first light emitting unit and an n-type doped organic layer in contact with the electron accepting organic layer and the second light emitting unit and wherein the n-type doped organic layer includes an organic gallium complex.

2. The tandem OLED device of claim 1 wherein the n-type doped organic layer further includes a phenanthroline derivative and lithium metal.

3. The tandem OLED device of claim 1 wherein the gallium complex is according to Formula (1):
GaL₃ Formula (1)
wherein:
the gallium is in a +3 valence state; and
each L represents a monoionic ligand such that the complex has an overall neutral charge and where at least one L must be organic.

4. The tandem OLED device of claim 3 wherein the n-type doped organic layer further includes a phenanthroline derivative and lithium metal.

5. The tandem OLED device of claim 3 wherein at least two of the L groups of the gallium complex are bidentate and contain at least one nitrogen that can form a dative bond to the gallium.

6. The tandem OLED device of claim 5 where the gallium complex is according to Formula (2): 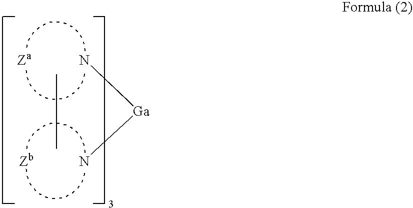
wherein each Z^{a} and Z^{b} is independently selected and represents the atoms necessary to complete an unsaturated heterocyclic ring.

7. The tandem OLED of claim 6 wherein the gallium complex is according to Formula (3). 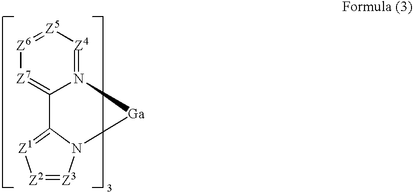
wherein:
each Z¹ through Z⁷ independently represents N or C—Y; and
Y represents hydrogen or an independently selected substituent.

8. The tandem OLED of claim 2 wherein the thickness of the n-doped organic layer is between 3 and 100 nm and the thickness of the electron accepting layer is between 3 and 100 nm.

9. The tandem OLED of claim 2 wherein the electron accepting organic layer includes a hexaazatriphenylene derivative.

10. The tandem OLED of claim 2 wherein the hexaazatriphenylene derivative is according to Formula (HATP): 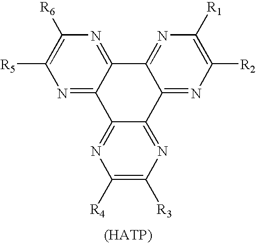
wherein R₁-R₆ are cyano groups.

11. The tandem OLED device of claim 1 where the n-type doped organic layer is divided into two sublayers in contact with each other; the sublayer which is in contact with the second light emitting unit includes a material having a LUMO energy level less negative than the LUMO energy level of the primary host material in the closest light emitting layer of the second light emitting unit.

12. A tandem OLED device having two spaced electrodes comprising:
a) first and second light-emitting units disposed between the electrodes that produce different emission spectra, the first light-emitting unit produces light that has multiple peaks at wavelengths longer than 500 nm and substantially no emission at wavelengths shorter than 480 nm, and the second light-emitting unit produces light that has substantial emission at wavelengths shorter than 500 nm; and
b) an intermediate connector disposed between each of the light-emitting units and having an electron accepting organic layer and an n-type doped organic layer and wherein the n-type doped organic layer includes an organic gallium complex.

13. The tandem OLED device of claim 12 wherein the n-type doped organic layer further includes a phenanthroline derivative and lithium metal.

14. The tandem OLED of claim 12 wherein the gallium complex is according to Formula (3). 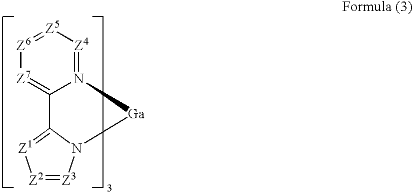
wherein:
each Z¹ through Z⁷ independently represents N or C—Y; and
Y represents hydrogen or an independently selected substituent.

15. The tandem OLED of claim 12 wherein the thickness of the n-doped organic layer is between 3 and 100 nm and the thickness of the electron accepting layer is between 3 and 100 nm.

16. The tandem OLED of claim 12 wherein the electron accepting organic layer includes a hexaazatriphenylene derivative.

17. The tandem OLED device of claim 1 wherein one of the spaced electrodes is reflective and the other is transmissive and the first light-emitting unit is disposed closer to the reflective electrode than the second light-emitting unit.
